(19) United States
(12) Patent Application Publication
(10) Pub. No.: US 2026/0121585 A1
(43) Pub. Date: Apr. 30, 2026

(54) AMPLIFIER USING VARYING PULSE WIDTHS

(71) Applicant: Texas Instruments Incorporated, Dallas, TX (US)

(72) Inventors: Aditya Agrawal, Bangalore (IN); Aditya Sundar, Bangalore (IN); Sumit Dubey, Bangalore (IN)

(21) Appl. No.: 19/345,962

(22) Filed: Sep. 30, 2025

(30) Foreign Application Priority Data
Oct. 25, 2024 (IN) 202441081457

(51) Int. Cl. H03F 1/02; H03F 3/181; H03K 5/00; H03K 5/05; H03K 5/08; H03K 7/08

(52) U.S. Cl. CPC H03F 1/0244; H03F 3/181; H03K 5/05; H03K 5/084; H03K 7/08; H03F 2200/03; H03F 2200/351; H03K 2005/00058

(57) ABSTRACT

In an embodiment, a device includes: modulation circuitry; switch circuitry having a first terminal, a second terminal, and a third terminal, the first terminal of the switch circuitry coupled to the modulation circuitry; pulse circuitry having a first terminal and a second terminal, the first terminal of the pulse circuitry coupled to the second terminal of the switch circuitry; and an output stage coupled to the third terminal of the switch circuitry and the second terminal of the pulse circuitry.

### CROSS-REFERENCE TO RELATED APPLICATION

This patent application claims the benefit of and priority to IN Provisional Patent Application No. 202441081457 filed Oct. 25, 2024, which is hereby incorporated herein by reference in its entirety.

### TECHNICAL FIELD

This description relates generally to an electronic system and method, and, in particular embodiments, to an amplifier using varying pulse widths.

### BACKGROUND

Electronic systems utilize amplifier circuitry for a wide range of operations, such as for signal modulation. Such amplifier circuitry generates a modulated signal by modulating a carrier signal based on an information signal. A load performs operations responsive to characteristics of the modulated output signal. In audio systems, audio amplifiers modulate a carrier signal based on an audio signal to generate a modulated signal that is a relatively higher power signal and has a relatively higher noise immunity than the original audio signal. Different audio amplifiers implement different types of modulation to provide different electrical or audio trade-offs, such as different power efficiency, noise immunity, etc. In operation, an audio amplifier can use the modulated signal to drive a speaker, which produces audible sound. Using amplifiers for signal modulation allows electronic systems to generate increasingly complex signals from relatively less complex signals.

### SUMMARY

In accordance to an embodiment, a device includes: modulation circuitry; switch circuitry having a first terminal, a second terminal, and a third terminal, the first terminal of the switch circuitry coupled to the modulation circuitry; pulse circuitry having a first terminal and a second terminal, the first terminal of the pulse circuitry coupled to the second terminal of the switch circuitry; and an output stage coupled to the third terminal of the switch circuitry and the second terminal of the pulse circuitry.

In accordance to an embodiment, a device includes: modulation circuitry capable of modulating audio signals to generate differential signals; and pulse circuitry coupled to the modulation circuitry, the pulse circuitry capable of: adjusting a pulse width of periodic pulses of the differential signals; setting outputs using the differential signals; increasing the pulse width of the periodic pulses across a plurality of cycles of the differential signals; and after a determination that the pulse width is greater than or equal to a threshold pulse width, stop adjusting the pulse width of the differential signals.

In accordance to an embodiment, a method includes: receiving an audio signal; modulating the audio signal to produce a modulated signal having a pulse width; setting the pulse width of the modulated signal to a minimum pulse width; providing the modulated signal having the minimum pulse width to a speaker; after providing the modulated signal to the speaker, monotonically increasing the pulse width of the modulated signal; and after the pulse width of the modulated signal is greater than or equal to a threshold, playing audio of the audio signal using the speaker.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an audio amplifier including audio modulation circuitry, pulse circuitry, and a controller;

FIG. 2 is a schematic diagram of an example implementation of the audio modulation circuitry of FIG. 1, according to an embodiment of the present disclosure;

FIG. 3 is a schematic diagram of an implementation of the pulse circuitry of FIG. 1 including delay cell circuitry, according to an embodiment of the present disclosure;

FIG. 4 is a schematic diagram of an implementation of the delay cell circuitry of FIG. 3, according to an embodiment of the present disclosure;

FIG. 5 is a block diagram of an implementation of the controller of FIG. 1, according to an embodiment of the present disclosure;

FIG. 6 is a flowchart of an embodiment method for operating the audio amplifier of FIG. 1, according to an embodiment of the present disclosure;

FIG. 7 is a flowchart of an embodiment method for operating the audio modulation circuitry of FIGS. 1 and 2, the pulse circuitry of FIGS. 1 and 3, and the controller of FIGS. 1 and 5 or, more generally, audio amplifier of FIG. 1, according to an embodiment of the present disclosure;

FIG. 8 is a flowchart of an embodiment for operating the audio modulation circuitry of FIGS. 1 and 2, the pulse circuitry of FIGS. 1 and 3, and the controller of FIGS. 1 and 5 or, more generally, audio amplifier of FIG. 1, according to an embodiment of the present disclosure;

FIGS. 9A, 9B, and 9C are timing diagrams of operations of the audio modulation circuitry of FIGS. 1 and 2, the pulse circuitry of FIGS. 1 and 3, and the controller of FIGS. 1 and 5 or, more generally, audio amplifier of FIG. 1 during soft-stepping operations, according to an embodiment of the present disclosure;

FIG. 10 is a timing diagram of operations of the pulse circuitry of FIGS. 1 and 3 or, more generally, audio amplifier of FIG. 1, according to an embodiment of the present disclosure;

FIG. 11 is a timing diagram of operations of the audio amplifier of FIG. 1 during soft-stepping operations, according to an embodiment of the present disclosure; and

FIGS. 12A and 12B are timing diagrams of operations of the audio modulation circuitry of FIGS. 1 and 2 or, more generally, the audio amplifier of FIG. 1 during frequency-stepping operations using a clock signal, according to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” or “an example” in this description indicate that a particular configuration, structure or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments relate reducing transient voltages at an output of an amplifier that uses varying pulse widths.

Electronic systems utilize amplifier circuitry for a wide range of operations, such as for signal modulation. Such amplifier circuitry generates a modulated signal by modulating a carrier signal based on an information signal. A load performs operations responsive to characteristics of the modulated output signal. In audio systems, audio amplifiers modulate a carrier signal based on an audio signal to generate a modulated signal that is a relatively higher power signal and has a relatively higher noise immunity than the original audio signal. Different audio amplifiers implement different types of modulation to provide different electrical or audio trade-offs, such as different power efficiency, noise immunity, etc. In operation, an audio amplifier can use the modulated signal to drive a speaker, which produces audible sound. Using amplifiers for signal modulation allows electronic systems to generate increasingly complex signals from relatively less complex signals.

Some embodiments advantageously reduce transient voltages at an output of an amplifier using varying pulse widths. In some embodiments, an audio amplifier implements soft-stepping or frequency-stepping to reduce transient voltages during turn on or turn off. During soft-stepping, the audio amplifier adjusts pulse widths of amplified signals by changing a duty cycle over time. During frequency-stepping, the audio amplifier adjusts pulse widths of amplified signals by changing a frequency of the carrier signal.

In both soft and frequency stepping, during turn on (e.g., start-up, power-up, etc.), the audio amplifier steadily increases the pulse width of the amplified signals from an initial relatively short pulse width to a relatively longer pulse width. For example, during soft stepping operations, the audio amplifier initially sets the duty cycle of the amplified signals to five percent and steadily increases pulse widths towards a final duty cycle of fifty percent. In another example, during frequency stepping, the audio amplifier initially sets the carrier signal to a relatively high frequency, which has relatively short pulse widths, and decreases the frequency towards a final switching frequency. After the pulse widths of the amplified signals are at the final pulse widths, the audio amplifier begins normal operations to playback audio.

Similarly, in both soft and frequency stepping, during turn off (e.g., shut-down, power-down, etc.), the audio amplifier steadily decreases the pulse widths of the amplified signals from an initial relatively long pulse width to a relatively shorter pulse width. For example, during soft stepping, the audio amplifier initially sets the duty cycle of the amplified signals to fifty percent and steadily decreases the duty cycle towards a final duty cycle of five percent. In another example, during frequency stepping, the audio amplifier initially sets the carrier signal to the switching frequency, which has relatively long pulse width, and increases the frequency towards a final relatively high frequency. After the pulse widths of the amplified signals are at the final pulse widths, the audio amplifier can power off.

In audio devices, transient voltages at the output can produce audible click or pop sounds. In some embodiments, advantageously, steadily increasing and decreasing the pulse width for the respective turn on or off operations of the audio amplifier reduces a transient voltage at the output. Advantageously, reducing the transient voltage during turn on and off operations reduces the magnitude of any audible click or pop sound from the output of the audio amplifier.

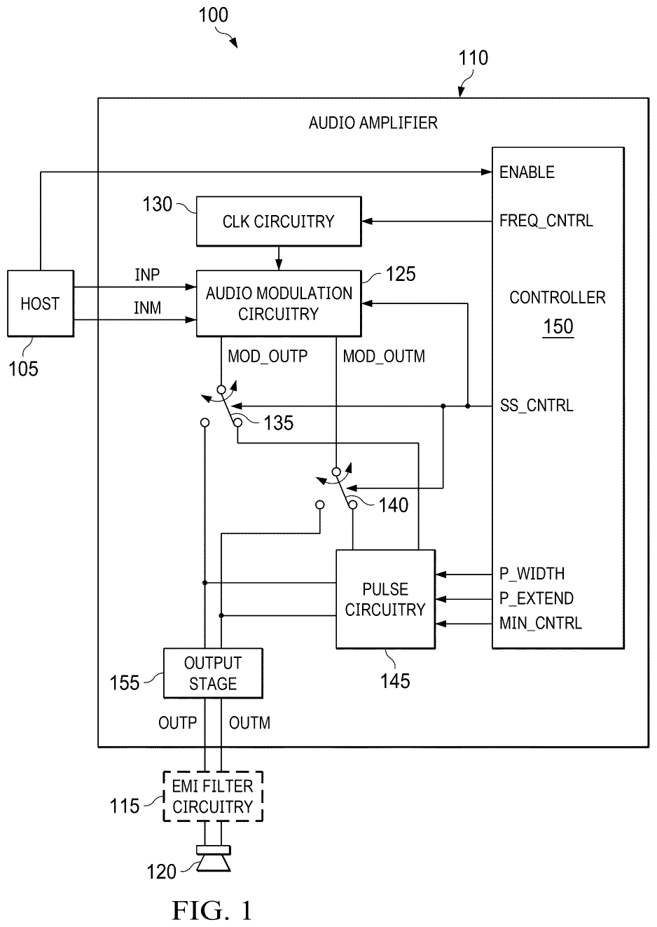

FIG. 1 illustrates a block diagram of audio system 100, according to an embodiment of the present disclosure. Audio system 100 includes audio amplifier 110, host 105, electromagnetic interference (EMI) filter circuitry 115, and speaker 120. The audio system 100 generates amplified signals (OUTP, OUTM) by modulating audio signals (INP, INM).

During normal operation, host 105 produces audio signals (INP, INM) and an enable signal (ENABLE). Host 105 may generate the audio signals (INP, INM) to electronically represent audio for playback. Host 105 may generate the enable signal (ENABLE) to control the turn-on and turn-off of the audio amplifier 110. Before providing audio for playback, host 105 may assert the enable signal (ENABLE) to turn on audio amplifier 110. Simultaneously, host 105 may set the audio signals (INP, INM) to a common mode voltage. After audio playback has completed, host 105 may deassert the enable signal (ENABLE) to turn off the audio amplifier 110.

As shown, the audio amplifier 110 is coupled to the host 105 and the EMI filter circuitry 115. The example audio amplifier 110 of FIG. 1 includes audio modulation circuitry 125, clock circuitry 130, switch circuitry 135, 140, pulse circuitry 145, a controller 150, and an output stage 155. The audio amplifier 110 receives the audio signal (INP), the audio signal (INM), and the enable signal (ENABLE) from the host 105. In some examples, the audio signals (INP, INM) may be referred to as input signals. The audio amplifier 110 may generate the amplified signals (OUTP, OUTM) responsive to modulating and amplifying the audio signals (INP, INM). In some examples, the audio amplifier 110 begins soft or frequency stepping to turn on or off responsive to edges of the enable signal (ENABLE). Alternatively, the audio amplifier 110 may turn on or off using an alternative scheme, such as a communication interface. After turning on using soft of frequency stepping, the audio amplifier 110 drives the speaker 120 by modulating and amplifying the audio signals (INP, INM). Such operations of the audio amplifier 110 are referred to as playback or normal operations.

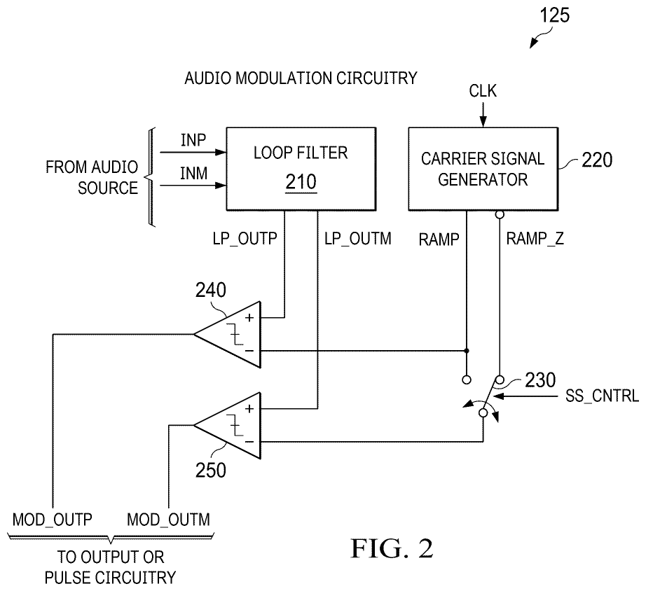

As shown, the audio modulation circuitry 125 is coupled to the host 105, the clock circuitry 130, the switch circuitry 135, 140, and the controller 150. The audio modulation circuitry 125 receives the audio signals (INP, INM), a reference clock (CLK), and a soft stepping control signal (SS_CNTRL). The audio modulation circuitry 125 generates modulated signals (MOD_OUTP, MOD_OUTM) by modulating audio signals (INP, INM) using the reference clock (CLK). The modulated signals (MOD_OUTP, MOD_OUTM) are differential signals, which represent logic of the audio signals (INP, INM) in accordance with a class of modulation. The audio modulation circuitry 125 is capable of using different classes of modulation to produce the modulated signals (MOD_OUTP, MOD_OUTM). The soft stepping control signal (SS_CNTRL) controls the class of modulation (also referred to as type of modulation) the audio modulation circuitry 125 implements. For example, if the soft stepping control signal (SS_CNTRL) is asserted, the audio modulation circuitry 125 implements a first class of modulation for soft stepping operations. In some such examples, if the soft stepping control signal (SS_CNTRL) is deasserted, the audio modulation circuitry 125 implements a second class of modulation for normal or frequency stepping operations. Advantageously, in the examples described herein, the audio modulation circuitry 125 uses BD modulation during soft stepping operations and AD modulation during normal or frequency stepping operations. An example of the audio modulation circuitry 125 is further illustrated and described in FIG. 2.

The clock circuitry 130 is coupled to the audio modulation circuitry 125 and the controller 150. The clock circuitry 130 receives a frequency control signal (FREQ_CNTRL). The clock circuitry 130 generates the reference clock (CLK) having a frequency set by the frequency control signal (FREQ_CNTRL). For example, the clock circuitry 130 changes the frequency of the reference clock (CLK) as the frequency control signal (FREQ_CNTRL) changes. The clock circuitry 130 provides the reference clock (CLK) to the audio modulation circuitry 125.

The switch circuitry 135, 140 couple the audio modulation circuitry 125 to one of the pulse circuitry 145 or the output stage 155 responsive to the soft stepping control signal (SS_CNTRL). During soft stepping operations, the switch circuitry 135, 140 provide the modulated signals (MOD_OUTP, MOD_OUTM) to the pulse circuitry 145. In some such examples, the controller 150 may assert the soft stepping control signal (SS_CNTRL) to toggle the switch circuitry 135, 140. When operating outside of soft stepping operations, such as during playback or frequency stepping operations, the switch circuitry 135, 140 provides the modulated signals (MOD_OUTP, MOD_OUTM) to the output stage 155.

The pulse circuitry 145 is coupled to the switch circuitry 135, 140, the controller 150, and the output stage 155. The pulse circuitry 145 receives the modulated signals (MOD_OUTP, MOD_OUTM), a pulse width signal (P_WIDTH), a pulse extension signal (P_EXTEND), and a minimum control signal (MIN_CNTRL). The pulse circuitry 145 converts the modulated signals (MOD_OUTP, MOD_OUTM) from BD modulated signals to low side recycling (LSR) modulated signals. LSR modulation subtracts BD modulated signals, such as the modulated signals (MOD_OUTP, MOD_OUTM), from one another. LSR modulated signals have pulses representing differences between pulses of the modulated signals (MOD_OUTP, MOD_OUTM). During soft stepping operations, the LSR modulated signals have relatively short pulses responsive to non-ideal differences between the modulated signals (MOD_OUTP, MOD_OUTM). For example, process variations in components of the audio modulation circuitry 125 set a duty cycle of the modulated signal (MOD_OUTP) slightly greater than a duty cycle of the modulated signal (MOD_OUTM). In another example, process variations in components of the audio modulation circuitry 125 set rising edges of the modulated signal (MOD_OUTP) using slightly different timing than components along the modulated signal (MOD_OUTM) signal path. In both examples, the LSR modulated signals reflect the differences between the modulated signals (MOD_OUTP, MOD_OUTM) as relatively brief pulses.

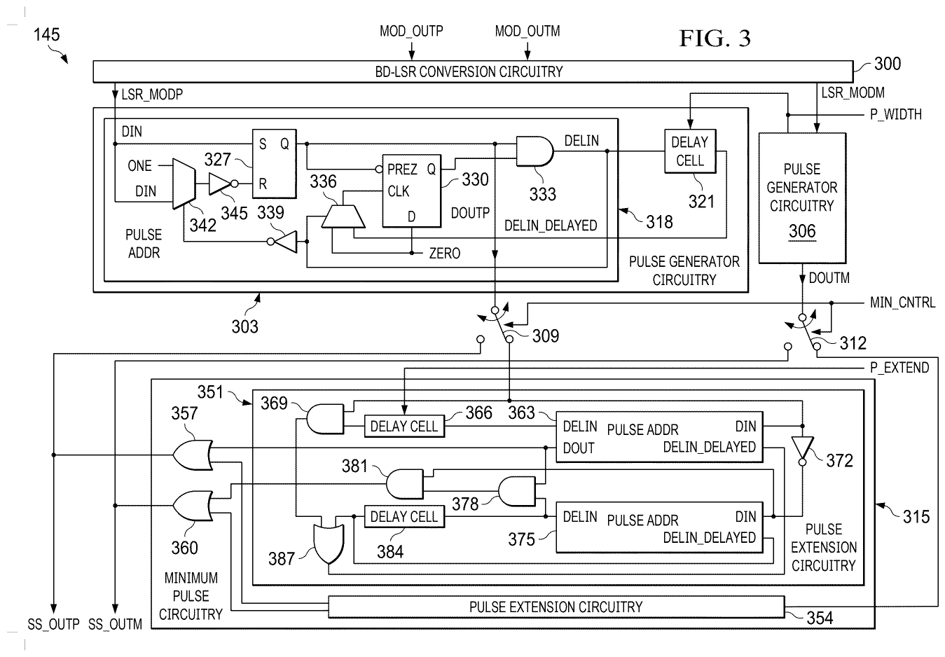

In such operations, the pulse circuitry 145 extends pulses of the LSR modulated signals to a pulse width set by the pulse width signal (P_WIDTH). For example, the pulse circuitry 145 extends pulses of the LSR modulated signals to have a pulse width corresponding to the pulse width signal (P_WIDTH). In some such examples, the pulse circuitry 145 makes the pulse widths of the LSR modulated signals uniform based on the pulse width signal (P_WIDTH). If the pulse width signal (P_WIDTH) is less than a threshold pulse width (e.g., minimum control signal (MIN_CNTRL) is asserted), the pulse circuitry 145 further extends pulses of the LSR modulated signals by an extension pulse width corresponding to the pulse extension signal (P_EXTEND). Also, the pulse circuitry 145 adds pulses having the extension pulse width to the LSR modulated signals. Advantageously, the extension and addition of pulses on the LSR modulated signals differentially cancel out to leave a differential representation of pulses corresponding to the pulse width signal (P_WIDTH). Advantageously, the adjusted pulse signals prevent the output stage 155 having to switch at relatively high speeds to represent relatively small pulse widths. An example of the pulse circuitry 145 is further illustrated and described in FIG. 3.

The controller 150 is coupled to the audio modulation circuitry 125, the clock circuitry 130, the switch circuitry 135, 140, and the pulse circuitry 145. The controller 150 receives the enable signal (ENABLE) from the host 105. The controller 150 generates the stepping control signal (SS_CNTRL), the frequency control signal (FREQ_CNTRL), the pulse width signal (P_WIDTH), the pulse extension signal (P_EXTEND), and the minimum control signal (MIN_CNTRL). The controller 150 begins soft or frequency stepping operations responsive to the enable signal (ENABLE) indicating a turn on or off of the audio amplifier 110. The controller 150 starts soft stepping operations by asserting the stepping control signal (SS_CNTRL) and setting the pulse width signal (P_WIDTH) to an initial value. The controller 150 de-asserts the soft stepping control signal (SS_CNTRL) after completing soft stepping operations.

During soft stepping operations to turn on the audio amplifier 110, the controller 150 increases the pulse width signal (P_WIDTH) to step-up (increase) pulse widths of the amplified signals (OUTP, OUTM) at the output of the audio amplifier 110. In some embodiments, the controller 150 completes soft stepping operations once the pulse width signal (P_WIDTH) is, equal to, e.g., a fifty percent duty cycle. For example, during turn on, the controller 150 may step the pulse width signal (P_WIDTH) up from, e.g., five percent to, e.g., fifty percent in, e.g., five percent increments.

During soft stepping operations to turn off the audio amplifier 110, after determining the audio signals (INP, INM) are idle, such as by the host 105 deasserting the enable signal (ENABLE), the controller 150 may decrease the pulse width signal (P_WIDTH) from, e.g., a fifty percent duty cycle. The controller 150 completes soft stepping operations with the pulse width signal (P_WDTH) being approximately equal to a minimum pulse. For example, during turn off, the controller 150 steps the pulse width signal (P_WIDTH) down from, e.g., fifty percent to, e.g., five percent in, e.g., five percent increments.

During frequency stepping operations to turn on the audio amplifier 110, the controller 150 may decrease the frequency of the frequency control signal (FREQ_CNTRL) to step-up (increase) pulse widths of the amplified signals (OUTP, OUTM) at the output of the audio amplifier 110. The controller 150 completes frequency stepping operations once the frequency of the frequency control signal (FREQ_CNTRL) is at a switching frequency. For example, during turn on, the controller 150 may decrease the frequency control signal (FREQ_CNTRL) from, e.g., fifty megahertz (MHz) to, e.g., two megahertz (MHz) in, e.g., four increments. In such examples, pulse widths of the amplified signals (OUTP, OUTM) increase as the frequency control signal (FREQ_CNTRL) decreases the frequency of the reference clock (CLK).

During frequency stepping operations to turn off the audio amplifier 110, after determining the audio signals (INP, INM) are idle, such as by the host 105 de-asserting the enable signal (ENABLE), the controller 150 may increase the frequency control signal (FREQ_CNTRL) from the switching frequency of the audio amplifier 110 (e.g., two megahertz). The controller 150 completes frequency stepping operations if the frequency control signal (FREQ_CNTRL) is at a maximum frequency, which corresponds to a minimum pulse width. For example, during turn off, the controller 150 may increase the frequency control signal (FREQ_CNTRL) from, e.g., two megahertz (MHz) to, e.g., fifty megahertz (MHz) in, e.g., four increments. In such examples, pulse widths of the amplified signals (OUTP, OUTM) decrease as the frequency control signal (FREQ_CNTRL) increases the frequency of the reference clock (CLK).

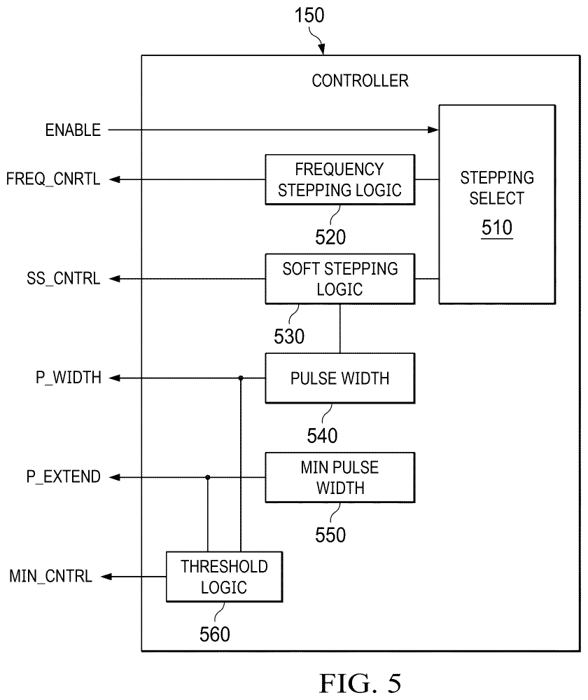

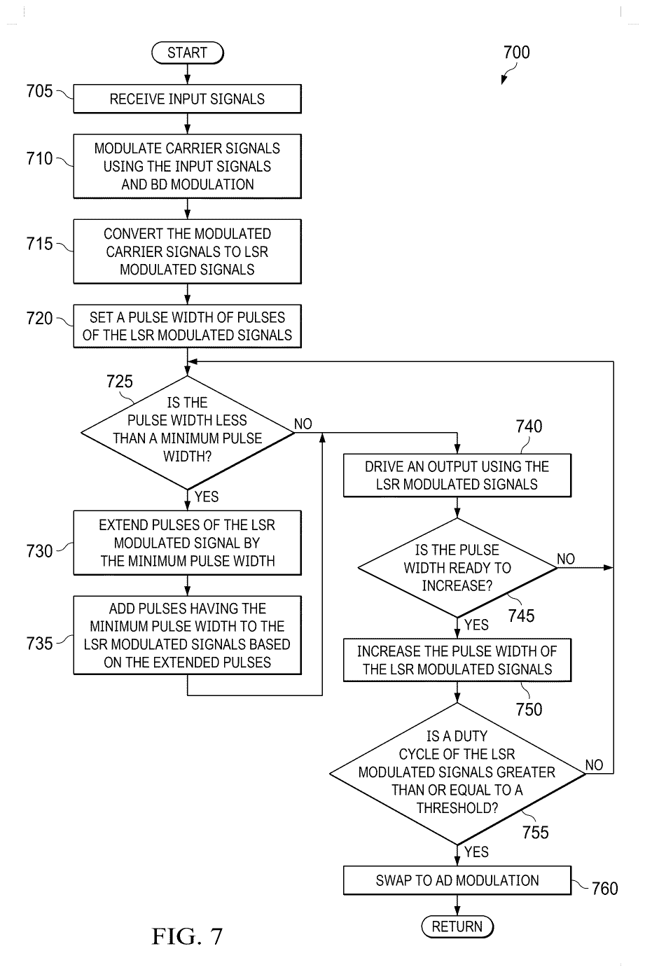

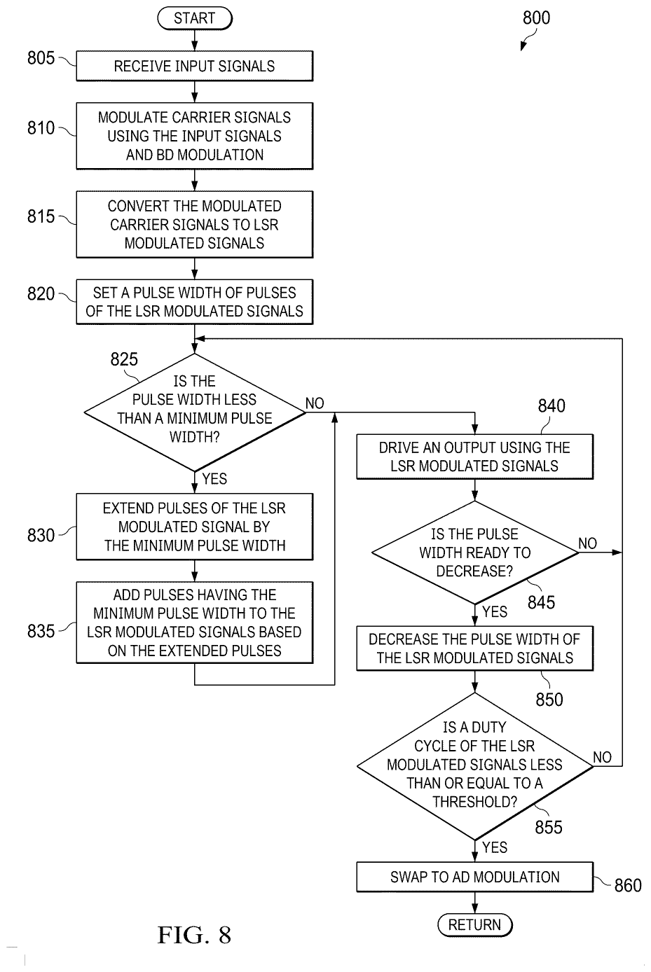

In both soft and frequency stepping, the controller 150 may increase or decrease the pulse widths of the amplified signals (OUTP, OUTM) to turn on or off the audio amplifier 110. An example of the controller 150 is further illustrated and described in FIG. 5. Example operations to turn on the audio amplifier 110 using soft stepping is further illustrated and described in FIG. 7. Example operations to turn off the audio amplifier 110 using soft stepping is further illustrated and described in FIG. 8.

The output stage 155 is coupled to the switch circuitry 135, 140, the pulse circuitry 145, and the EMI filter circuitry 115. The output stage 155 receives modulated signals from either the audio modulation circuitry 125, via the switch circuitry 135, 140, or the pulse circuitry 145. The output stage 155 generates the amplified signals (OUTP, OUTM) responsive to amplifying the modulated signals. The output stage 155 provides the amplified signals (OUTP, OUTM) to the speaker 120 via the EMI filter circuitry 115.

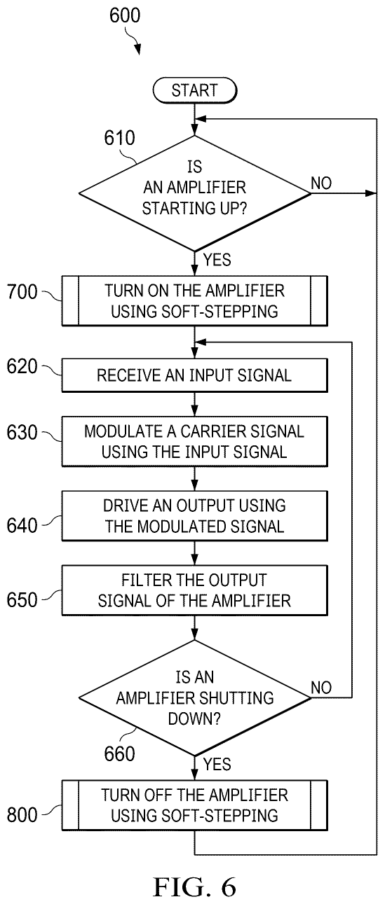

In some embodiments, stepping up a pulse width of the amplified signals (OUTP, OUTM) of audio amplifier 110 may advantageously reduce a transient voltage during turn on. In some embodiments, stepping down the pulse width of the amplified signals (OUTP, OUTM) of audio amplifier 110 may advantageously reduce a transient voltage during turn off. In some embodiments, reducing transient voltages of the amplified signals (OUTP, OUTM) may advantageously reduce a likelihood of producing an audible crack or pop sound from speaker 120. Example operations of the audio amplifier 110 or, more generally, the audio system 100 are further illustrated and described in connection with FIG. 6.

FIG. 2 is a schematic diagram of an example implementation of the audio modulation circuitry 125 of FIG. 1, according to an embodiment of the present disclosure. In the example of FIG. 1, the audio modulation circuitry 125 includes loop filter circuitry 210, a carrier signal generator 220, switch circuitry 230, and comparators 240, 250. The audio modulation circuitry 125 receives the audio signals (INP, INM), the reference clock (CLK), and the soft stepping control signal (SS_CNTRL). The audio modulation circuitry 125 modulates the audio signals (INP, INM) using the reference clock (CLK) to generate the modulated signals (MOD_OUTP, MOD_OUTM).

The loop filter 210 is coupled to the comparators 240, 250. The loop filter 210 receives the audio signals (INP, INM). The loop filter 210 filters the audio signals (INP, INM) to generate filtered signals (LP_OUTP, LP_OUTM). In some examples, the loop filter 210 is a multi-order low-pass filter, which filters relatively high frequency noise from the audio signals (INP, INM). The loop filter 210 provides the filtered signals (LP_OUTP, LP_OUTM) to the comparators 240, 250.

The carrier signal generator 220 is coupled to the comparator 240 and the switch circuitry 230. The carrier signal generator 220 receives the reference clock (CLK) having a reference frequency. The carrier signal generator 220 generates a carrier signal using the reference clock (CLK). In the example of FIG. 2, the carrier signal generator 220 generates a triangular carrier signal, which is referred to as a ramp signal (RAMP). In some examples, the carrier signal generator 220 also generates an inverted ramp signal (RAMP_Z), which is a logical inverse of the ramp signal (RAMP). The carrier signal generator 220 sets the frequency of the ramp signal (RAMP) to match the frequency of the reference clock (CLK). The carrier signal generator 220 provides the ramp signal (RAMP) at a non-inverting terminal and the inverted ramp signal (RAMP_Z) at an inverting terminal.

The switch circuitry 230 is coupled to the carrier signal generator 220 and the comparator 250. The switch circuitry 230 receives the ramp signal (RAMP), the inverted ramp signal (RAMP_Z), and the soft stepping control signal (SS_CNTRL). The switch circuitry 230 provides one of the ramp signal (RAMP) or the inverted ramp signal (RAMP_Z) to the comparator 250. In operation, the soft stepping control signal (SS_CNTRL) controls the switch circuitry 230. During soft stepping operations, the soft stepping control signal (SS_CNTRL) sets the switch circuitry 230 to provide the inverted ramp signal (RAMP_Z) to the comparator 250. During normal or frequency stepping operations, the soft stepping control signal (SS_CNTRL) sets the switch circuitry 230 to provide the ramp signal (RAMP) to the comparator 250.

The comparator 240 is coupled to the loop filter 210 and the carrier signal generator 220. The comparator 240 receives the filtered output (LP_OUTP) and the ramp signal (RAMP). The comparator 240 generates the modulated signal (MOD_OUTP) by comparing the filtered output (LP_OUTP) to the ramp signal (RAMP). For example, if the ramp signal (RAMP) is greater than the filtered output (LP_OUTP), the comparator 240 sets (e.g., asserts) the modulated signal (MOD_OUTP). In such examples, if the ramp signal (RAMP) is less than the filtered output (LP_OUTM), the comparator 240 clears (e.g., deasserts) the modulated signal (MOD_OUTP).

The comparator 250 is coupled to the loop filter 210 and the carrier signal generator 220, via the switch circuitry 230. The comparator 250 receives the filtered signal (LP_OUTM) and one of the ramp signal (RAMP) or the inverted ramp signal (RAMP_Z). During soft stepping operations, the comparator 250 compares the filtered signal (LP_OUTM) to the inverted ramp signal (RAMP_Z). In such examples, the comparator 240 generates the modulated signal (MOD_OUTM) by comparing the filtered output (LP_OUTM) to the inverted ramp signal (RAMP_Z). During such operations, the audio modulation circuitry 125 implements BD modulation to generate the modulated signals (MOD_OUTP, MOD_OUTM). In BD modulation, the modulated signals (MOD_OUTP, MOD_OUTM) can represent three different logical states (e.g., −1, 0, 1).

Alternatively, during normal or frequency stepping operations, the comparator 250 compares the filtered signal (LP_OUTM) to the ramp signal (RAMP). In such examples, the comparator 250 generates the modulated signal (MOD_OUTM) by comparing the filtered output (LP_OUTM) to the ramp signal (RAMP). During such operations, the audio modulation circuitry 125 implements AD modulation to generate the modulated signals (MOD_OUTP, MOD_OUTM). In AD modulation, the modulated signals (MOD_OUTP, MOD_OUTM) can represent two different logical states (e.g., 0, 1).

In some embodiments, when producing audible sound in normal operations, AD modulation may advantageously lower distortion in comparison to BD modulation. In some embodiments, when producing audible sound is undesirable, such as during turn on and off operations, BD modulation may advantageously consume less power, which reduces the likelihood of producing an audible crack or pop sound, in comparison to AD modulation. In some embodiments, as further described in connection with FIG. 3, the pulse circuitry 145 advantageously converts BD modulated signals to LSR modulated signals to further reduce power consumption and the likelihood of producing an audible crack or pop sound.

FIG. 3 is a schematic diagram of an example implementation of the pulse circuitry 145 of FIG. 1, according to an embodiment of the present disclosure. In the example of FIG. 3, the pulse circuitry 145 includes conversion logic circuitry 300, pulse generator circuitry 303, 306, switch circuitry 309, 312, and minimum pulse circuitry 315. The pulse circuitry 145 receives the modulated signals (MOD_OUTP, MOD_OUTM), the pulse width signal (P_WIDTH), the pulse extension signal (P_EXTEND), and the minimum control signal (MIN_CNTRL). The pulse circuitry 145 generates soft stepping signals (SS_OUTP, SS_OUTM) using the modulated signals (MOD_OUTP, MOD_OUTM) and the pulse width signal (P_WIDTH).

The conversion logic circuitry 300 is coupled to the pulse generator circuitry 303, 306. The conversion logic circuitry 300 receives the modulated signals (MOD_OUTP, MOD_OUTM). The conversion logic circuitry 300 converts the modulated signals (MOD_OUTP, MOD_OUTM) from BD modulation to LSR modulation. In operations, the conversion logic circuitry 300 implements LSR modulation by subtracting the modulated signals (MOD_OUTP, MOD_OUTM) from each other. The conversion logic circuitry 300 generates LSR modulated signals (LSR_MODP, LSR_MODM) as converted signals having pulses that represent the difference between the modulated signals (MOD_OUTP, MOD_OUTM). For example, when the modulated signals (MOD_OUTP, MOD_OUTM) are both logical ones, the conversion logic circuitry 300 produces LSR modulated signals (LSR_MODP, LSR_MODM) that are both logical zeros. In such examples, the conversion logic circuitry 300 subtracts the shared state of the modulated signals (MOD_OUTP, MOD_OUTM) to produce the LSR modulated signals (LSR_MODP, LSR_MODM).

In practice, variations between components producing each of the modulated signals (MOD_OUTP, MOD_OUTM) produce variations between rising and falling edges. For example, the switch circuitry 230 adds a propagation delay along the modulated signal (MOD_OUTM) path that is not present in the path of the comparator 240, which produces the modulated signal (MOD_OUTP). In operation, the conversion logic circuitry 300 does not account for the non-ideal timing characteristics of the modulated signals (MOD_OUTP, MOD_OUTM). In such operations, the conversion logic circuitry 300 produces relatively short pulses corresponding to the non-ideal differences between the modulated signals (MOD_OUTP, MOD_OUTM) on the LSR modulated signals. Instead of deglitching the pulses, the conversion circuitry 300 provides the pulses to the pulse generator circuitry 303, 306 to simplify soft stepping.

The pulse generator circuitry 303, 306 is coupled to the conversion logic circuitry 300 and the switch circuitry 309, 312. The example pulse generator circuitry 303 of FIG. 3 includes pulse adder circuitry 318 and delay cell circuitry 321. In the example of FIG. 3, components of the pulse generator circuitry 303 are illustrated and described. However, it is to be understood that the pulse generator circuitry 306 is an instance of the pulse generator circuitry 303, which contains similar components to those illustrated in connection with pulse generator circuitry 303. The pulse generator circuitry 303, 306 receive the LSR modulated signals (LSR_MODP, LSR_MODM) and the pulse width signal (P_WIDTH). The pulse generator circuitry 303, 306 produce the adjusted pulse signals (DOUTP, DOUTM) having uniform pulses with pulse widths corresponding to the pulse width signal (P_WIDTH).

The pulse adder circuitry 318 is coupled to the conversion logic circuitry 300, the switch circuitry 309, and the delay cell circuitry 321. The example pulse adder circuitry 318 of FIG. 3 includes a latch 327, a flip-flop 330, a logic device 333, multiplexers 336, 342, and inverters 339, 345. The pulse adder circuitry 318 receives the LSR modulated signal (LSR_MODP) from the conversion logic circuitry 300. The pulse adder circuitry 318 generates the adjusted pulse signal (DOUTP) responsive to the LSR modulated signal and a delay of the delay cell circuitry 321.

In operation, the pulse adder circuitry 318 produces a rising edge on the adjusted pulse signal (DOUTP) responsive to a rising edge of the LSR modulated signal (LSR_MODP). For example, a rising edge of the LSR modulated signal (LSR_MODP) sets the latch 327 and the flip-flop 330 to assert the adjusted pulse signal (DOUTP). The delay cell circuitry 321 delays the rising edge of the adjusted pulse signal (DOUTP) by a duration corresponding to the pulse width signal (P_WIDTH). An example of the delay cell circuitry 321 is further illustrated and described in connection with FIG. 3.

In such operations, the multiplexer 342 and the inverter 345 prevent the latch 327 from resetting until the rising edge of the adjusted pulse signal (DOUTP) propagates through the delay cell circuitry 321. For example, if the pulse width signal (P_WIDTH) corresponds to a pulse width of twenty nanoseconds (ns), the delay cell circuitry 321 delays adjusting the multiplexers 336, 342 or, more generally, the latch 327 and the flip-flop 330 by twenty nanoseconds. In such examples, the multiplexers 336, 342 and the inverters 339, 345 modify (e.g., reset) the latch 327 and the flip-flop 330 to generate a falling edge on (e.g., deassert) the adjusted pulse signal (DOUTP). Also, the flip-flop 330 and the multiplexer 336 allow pulses of the LSR modulated signal (LSR_MODP) having pulse widths greater than the width of the pulse width signal (P_WIDTH) to set the adjusted pulse signal (DOUTP). Advantageously, the pulse generator circuitry 303, 306 produce pulses on the adjusted pulse signals (DOUTP, DOUTM) having pulse widths corresponding to the pulse width signal (P_WIDTH).

The switches 309, 312 are coupled to the pulse generator circuitry 303, 306 and the minimum pulse circuitry 315. The switches 309, 312 receive the minimum control signal (MIN_CNTRL). The minimum control signal (MIN_CNTRL) controls the switches 309, 312 by directing the adjusted pulse signals (DOUTP, DOUTM) to either the minimum pulse circuitry 315 or the output stage 155. In some examples, if the minimum control signal (MIN_CNTRL) is asserted, the switch circuitry 309, 312 provide the adjusted pulse signals (DOUTP, DOUTM) to the minimum pulse circuitry 315. In some other examples, if the minimum control signal (MIN_CNTRL) is deasserted, the switch circuitry 309, 312 set the soft stepping signals (SS_OUTP, SS_OUTM) as the adjusted pulse signals (DOUTP, DOUTM). In the example of FIG. 3, the switch circuitry 309, 312 are illustrated and described using toggle switches. Alternatively, in other examples, the switch circuitry 309, 312 may be implemented by alternative components, such as transistors.

The minimum pulse logic 315 is coupled to the switch circuitry 309, 312. The minimum pulse logic 315 receives the adjusted pulse signals (DOUTP, DOUTM) and the pulse extension signal (P_EXTEND). The example minimum pulse logic 315 of FIG. 3 includes pulse extension circuitry 351, 354 and logic devices 357, 360. In some examples, the minimum pulse logic 315 extends a pulse width of a first one of the adjusted pulse signals (DOUTP, DOUTM) by a minimum pulse width corresponding to the pulse extension signal (P_EXTEND). In such examples, the minimum pulse logic 315 adds pulses having the minimum pulse width to both of the adjusted pulse signals (DOUTP, DOUTM). For example, the minimum pulse logic 315 adds a first pulse to the adjusted pulse signal (DOUTP) by extending a pulse width and adds a second pulse to the adjusted pulse signal (DOUTM). The minimum pulse logic 315 sets the soft stepping signals (SS_OUTP, SS_OUTM) using the respective added pulses.

The pulse extension circuitry 351, 354 are coupled to the switch circuitry 309, 312 and the logic devices 357, 360. The pulse extension circuitry 351, 354 receives the adjusted pulse signals (DOUTP, DOUTM) and the pulse extension signal (P_EXTEND). The example pulse extension circuitry 351 of FIG. 3 includes pulse adder circuitry 363, delay cell circuitry 366, logic device 369, inverter 372, pulse adder circuitry 375, logic devices 378, 381, delay cell circuitry 384, and logic device 387. In the example of FIG. 3, the pulse adder circuitry 318 is illustrated and described as an example implementation of the pulse adder circuitry 363, 375. Similar to the pulse adder circuitry 318 and the delay cell circuitry 321, the pulse adder circuitry 363, 375, the delay cell circuitry 366, 384, and the logic devices 369, 378, 381, 387 adjust a pulse width of the adjusted pulse signals (DOUTP, DOUTM).

In operation, if the adjusted pulse signal (DOUTP) has a pulse, the pulse adder circuitry 363, the delay cell circuitry 366, and the logic devices 369, 387 extend the pulse based on the pulse extension signal (P_EXTEND). The pulse extension signal (P_EXTEND) represents the minimum pulse width of the soft stepping signals (SS_OUTP, SS_OUTM). In some such examples, the pulse adder circuitry 375, the logic devices 378, 381, 387, and the delay cell circuitry 384 add a pulse having the minimum pulse width at the output of the pulse extension circuitry 351. Similarly, the pulse extension circuitry 354 extends and adds pulses responsive to pulses of the adjusted pulse signal (DOUTM).

In such operations, the logic devices 357, 360 set the soft stepping signals (SS_OUTP, SS_OUTM) by logically combining outputs of the pulse extension circuitry 351, 354. For example, the logic device 357, 360 set the pulses of the soft stepping signals (SS_OUTP, SS_OUTM) to pulses having a pulse width greater than or equal to the minimum pulse width. Such a minimum pulse width prevents relatively high-speed switching of the output stage 155.

In some embodiments, changing the pulse width of the soft stepping signals (SS_OUTP, SS_OUTM) advantageously reduces a transient voltage during start-up or shutdown of the audio amplifier 110. In some embodiments, reducing the transient voltage using the soft stepping signals (SS_OUTP, SS_OUTM) advantageously reduces a likelihood of creating an audible crack or pop sound.

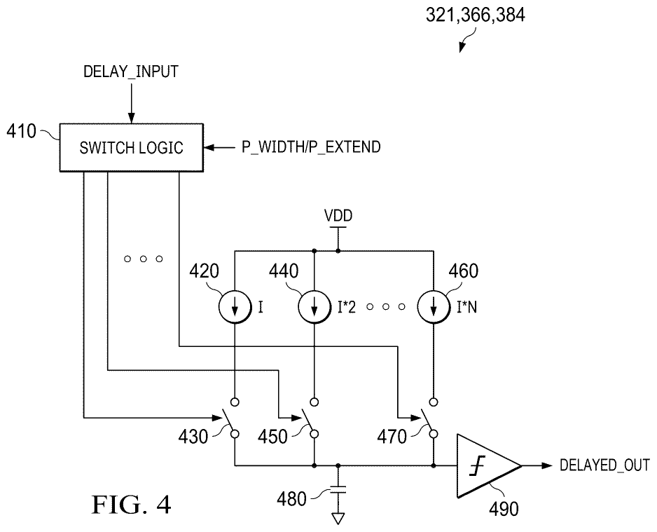

FIG. 4 is a schematic diagram of an example implementation of the delay cell circuitry 321, 366, 384 of FIG. 3 according to an embodiment of the present disclosure. The example delay cell circuitry 321 of FIG. 4 includes switch logic 410, current sources 420, 440, 460, switches 430, 450, 470, a capacitor 480, and a comparator 490. The delay cell circuitry 321, 366, 384 of FIG. 4 receives a delay signal (DELAY_INPUT) and one of the pulse width or pulse extension signals (P_WIDTH, P_EXTEND). The delay signal (DELAY_INPUT) represents a signal to be delayed. The delay cell circuitry 321, 366, 384 delays edges of the delay signal (DELAY_INPUT) to generate a delayed signal (DELAY_OUT).

The switch logic 410 is coupled to the switches 430, 450, 470. The switch logic 410 receives the delay signal (DELAY_INPUT) and one of the pulse width or pulse extension signals (P_WIDTH, P_EXTEND). The switch logic 410 closes one or more of the switches 430, 450, 470 responsive to an edge of the delay signal (DELAY_INPUT). The switch logic 410 determines which of the switches 430, 450, 470 to close responsive to the one of the pulse width or pulse extension signals (P_WIDTH, P_EXTEND). For example, if the one of the pulse width or pulse extension signals (P_WIDTH, P_EXTEND) is a first value, the switch logic 410 controls the switching of the switch 430. In some such examples, if the one of the pulse width or pulse extension signals (P_WIDTH, P_EXTEND) is a second value, the switch logic 410 controls the switching of the switch 450. Although in the example of FIG. 4, the delay cell circuitry 321, 366, 384 has three switches, in other examples, the switch logic 410 may control any number (N) of switches.

The current sources 420, 440, 460 are coupled to the switches 430, 450, 470. The current sources 420, 440, 460 respectively supply a current of a different magnitude. For example, the current source 420 supplies a first current (I) and the current source 440 supplies a second current (2*I), which is twice the first current. The switch logic 410 and the switches 430, 450, 470 control which of the current sources 420, 440, 460 charge the capacitor 480.

The switches 430, 450, 470 are coupled to the switch logic 410, the current sources 420, 440, 460, the capacitor 480, and the comparator 490. The switches 430, 450, 470 route current from one or more of the current sources 420, 440, 460 to the capacitor 480 responsive to the switch logic 410.

The capacitor 480 is coupled to the switches 430, 450, 470 and the comparator 490. The capacitor 480 integrates charge of current from one or more of the current sources 420, 440, 460 to set a voltage at the input of the comparator 490. In operation, the speed at which the capacitor 480 charges proportional to the magnitude of current supplied by the switches 430, 450, 470. For example, closing the switch 430 charges the capacitor 480 at a first rate, closing the switch 450 charges the capacitor 480 at a second rate, and closing the switch 470 charges the capacitor at a third rate. In some such examples, the switch logic 410 determines to use the first, second, or third rate responsive to the one of the pulse width or pulse extension signals (P_WIDTH, P_EXTEND).

The comparator 490 is coupled to the switches 430, 450, 470 and the capacitor 480. The comparator 490 receives the voltage of the capacitor 480. The comparator 490 sets the delayed signal (DELAY_OUT) responsive to a comparison of the voltage of the capacitor 480 to a threshold voltage. In operation, the comparator 490 sets the delayed signal (DELAY_OUT) responsive to the voltage of the capacitor 480 exceeding the threshold voltage. In such operations, the rate of charge of the capacitor 480 corresponds to the delay the comparator 490 has in setting the delayed signal (DELAY_OUT). Advantageously, the delay cell circuitry 321, 366, 384 has a programmable delay, which is set by increasing or decreasing the current supplied to the capacitor 480.

FIG. 5 is a block diagram of an example implementation of the controller 150 of FIG. 1 according to an embodiment of the present disclosure. The example controller 150 of FIG. 5 includes stepping select circuitry 510, frequency stepping logic 520, soft stepping logic 530, pulse width circuitry 540, minimum pulse width circuitry 550, and threshold logic 560. In the example of FIG. 5, the controller 150 receives the enable signal (ENABLE). The controller 150 implements one of frequency or soft stepping operations to turn on and off the audio amplifier 110. During frequency stepping operations, the controller 150 produces the frequency control signal (FREQ_CNTRL). During soft stepping operations, the controller 150 produces the frequency control signal (FREQ_CNTRL), the soft stepping control signal (SS_CNTRL), the pulse width signal (P_WIDTH), the pulse extension signal (P_EXTEND), and the minimum pulse control signal (MIN_CNTRL). During both frequency and soft stepping operations, the controller 150 adjusts the pulse width of the amplified signals (OUTP, OUTM) at outputs of the audio amplifier 110. In some embodiments, adjusting the pulse widths of the amplified signals (OUTP, OUTM) advantageously reduces the transient voltage at the speaker 120. In some embodiments, decreasing the transient voltage at the speaker 120 advantageously decreases the likelihood of producing an audible crack or pop sound.

The stepping select circuitry 510 (also referred to as stepping select logic) is coupled to the frequency stepping logic 520 and the soft stepping logic 530. The stepping select circuitry 510 receives the enable signal (ENABLE). The stepping select circuitry 510 detects changes to the enable signal (ENABLE) as either a turn on or turn off event of the audio amplifier 110. For example, the stepping select circuitry 510 determines to turn on the audio amplifier 110 responsive to a rising edge of the enable signal (ENABL). Alternatively, the stepping select circuitry 510 determines to turn off the audio amplifier 110 responsive to a falling edge of the enable signal (ENABLE). Once the stepping select circuitry 510 determines the audio amplifier 110 is experiencing a turn on or off event, the stepping select circuitry 510 initiates either frequency or soft stepping using the respective one of the frequency or soft stepping logics 520, 530. In some examples, the stepping select circuitry 510 is set to initiate a predetermined one of the frequency or soft stepping logics 520, 530. For example, during manufacturing the stepping select circuitry 510 is set to initiate the soft stepping logic 530 responsive to a turn on or turn off event of the audio amplifier 110. Alternatively, the stepping select circuitry 510 may use additional logic to select one of the frequency or soft stepping logics 520, 530.

The frequency stepping logic 520 is coupled to the stepping select circuitry 510. The frequency stepping logic 520 receives an indication from the stepping select circuitry 510 to begin frequency stepping operations for a turn on or turn off event of the audio amplifier 110. The frequency stepping logic 520 generates the frequency control signal (FREQ_CNTRL) to implement frequency stepping operations. Unlike in soft stepping, frequency stepping manipulates the pulse widths of the amplified signals (OUTP, OUTM) by changing the frequency of the carrier signal (e.g., the ramp signal (RAMP) of FIG. 2). For example, at an initial time, the frequency stepping logic 520 sets the frequency control signal (FREQ_CNTRL) to produce the ramp signal (RAMP) with a relatively high frequency, which has a relatively short pulse width. In such operations, the frequency stepping logic 520 adjusts the frequency control signal (FREQ_CNTRL) in steps to slowly decrease the frequency of the ramp signal (RAMP) until a target pulse width is achieved. In some embodiments, frequency stepping using the carrier signal of the audio modulation circuitry 125 advantageously reduces complexity and transient voltages at the speaker 120. In some embodiments, reducing the transient voltages at the speaker 120 advantageously reduces the likelihood of producing an audible crack or pop during turn on or off operations of the audio amplifier 110.

The soft stepping logic 530 is coupled to the stepping select circuitry 510 and the pulse width circuitry 540. The soft stepping logic 530 receives an indication from the stepping select circuitry 510 to begin soft stepping operations for a turn on or turn off event of the audio amplifier 110. The soft stepping logic 530 produces the soft stepping control signal (SS_CNTRL) that represents whether soft stepping operations are occurring. During soft stepping operations, the soft stepping logic 530 adjusts the pulse width circuitry 540 to increase, during turn on, or decrease, during turn off, the pulse width of the amplified signals (OUTP, OUTM) to/from a minimum pulse width. In some embodiments, soft stepping the pulse width of the amplified signals (OUTP, OUTM) advantageously reduces transient voltages at the speaker 120. In some embodiments, reducing the transient voltages at the speaker 120 advantageously reduces the likelihood of producing an audible crack or pop during turn on or off operations of the audio amplifier 110.

The pulse width circuitry 540 (also referred to as pulse width logic) is coupled to the soft stepping logic 530. The pulse width circuitry 540 generates the pulse width signal (P_WIDTH) to control a pulse width of the amplified signals (OUTP, OUTM). In some examples, the pulse width circuitry 540 generates the pulse width signal (P_WIDTH) responsive to receiving pulse width details from the soft stepping logic 530. For example, the pulse width circuitry 540 receives a start pulse width, an end pulse width, a pulse width increment, and a step duration. In some such examples, the pulse width circuitry 540 sets the pulse width signal (P_WIDTH) to the start pulse width and forms steps by adjusting the pulse width using the pulse width increment and step duration. Advantageously, the pulse width circuitry 540 sets the pulse width of the amplified signals (OUTP, OUTM) for soft stepping.

The minimum pulse width circuitry 550 produces the pulse extension signal (P_EXTEND). The pulse extension signal represents a minimum pulse width of the amplified signals (OUTP, OUTM). In some examples, the minimum pulse width circuitry 550 is a predefined value, such as a value set at a time of manufacture, or a dynamic value, which is set by the controller 150. In both examples, the minimum pulse width of the minimum pulse width circuitry 550 is set to prevent switching of the output stage 155 above a threshold frequency. In operation, limiting the switching frequency of the output stage 155 using the minimum pulse width reduces the likelihood of failing to drive the amplified signals (OUTP, OUTM).

The threshold logic 560 is coupled to the pulse width circuitry 540 and the minimum pulse width circuitry 550. The threshold logic 560 receives the pulse width signal (P_WIDTH) and the pulse extension signal (P_EXTEND). The threshold logic 560 compares the pulse width and extension signals (P_WIDTH, P_EXTEND) to produce the minimum control signal (MIN_CNTRL). In some examples, if the pulse width signal (P_WIDTH) corresponds to a pulse width less than the pulse width extension signal (P_EXTEND), the threshold logic 560 asserts the minimum control signal (MIN_CNTRL). Alternatively, if the pulse width signal (P_WIDTH) corresponds to a pulse width greater than the pulse width extension signal (P_EXTEND), the threshold logic 560 deasserts the minimum control signal (MIN_CNTRL). Advantageously, the minimum control signal (MIN_CNTRL) controls the switch circuitry 309, 312 responsive to a comparison of the current pulse width of the pulse width signal (P_WIDTH) to the pulse extension signal (P_EXTEND). Advantageously, the minimum pulse circuitry 315 can extend and add pulses of the amplified signals (OUTP, OUTM) when the minimum control signal (MIN_CNTRL) is asserted.

While an example manner of implementing the audio amplifier 110 is illustrated in FIGS. 1, 2, 3, 4, and 5, one or more of the elements, processes, and/or devices illustrated in FIGS. 1, 2, 3, 4, and 5 may be combined, divided, re-arranged, omitted, eliminated, and/or implemented in any other way. Further, the audio modulation circuitry 125 of FIGS. 1 and 2, the clock circuitry 130 of FIG. 1, the pulse circuitry 145 of FIGS. 1 and 3, and the controller 150 of FIGS. 1 and 5 or, more generally, the example the audio amplifier 110 of FIG. 1, may be implemented by hardware alone or by hardware in combination with software and/or firmware. Thus, for example, any of the audio modulation circuitry 125 of FIGS. 1 and 2, the clock circuitry 130 of FIG. 1, the pulse circuitry 145 of FIGS. 1 and 3, and the controller 150 of FIGS. 1 and 5 or, more generally, the example audio amplifier 110 of FIG. 1, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the example audio modulation circuitry 125 of FIGS. 1 and 2, the clock circuitry 130 of FIG. 1, the pulse circuitry 145 of FIGS. 1 and 3, and the controller 150 of FIGS. 1 and 5 may include one or more elements, processes, and/or devices in addition to, or instead of, those illustrated in FIGS. 1, 2, 3, 4, and 5, and/or may include more than one of any or all of the illustrated elements, processes and devices.

Flowchart(s) representative of example machine readable instructions, which may be executed by programmable circuitry to implement and/or instantiate the audio modulation circuitry 125 of FIGS. 1 and 2, the clock circuitry 130 of FIG. 1, the pulse circuitry 145 of FIGS. 1 and 3, and the controller 150 of FIGS. 1 and 5 or, more generally the audio amplifier 110 of FIG. 1 and/or representative of example operations which may be performed by programmable circuitry to implement and/or instantiate the audio amplifier 110 of FIG. 1, are shown in FIGS. 6, 7, and 8. The machine-readable instructions may be one or more executable programs or portion(s) of one or more executable programs for execution by programmable circuitry. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. Similarly, the non-transitory computer readable storage medium may include one or more mediums.

Although the example program is described with reference to the flowchart(s) illustrated in FIGS. 6, 7, and 8, many other methods of implementing the example audio amplifier 110 of FIG. 1 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)).

As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

As mentioned above, the example operations of FIGS. FIGS. 6, 7, and 8 may be implemented using executable instructions (e.g., computer readable and/or machine-readable instructions) stored on one or more non-transitory computer readable and/or machine-readable media.

FIG. 6 is a flowchart of embodiment method 600 for operating audio amplifier 110,according to an embodiment of the present disclosure. Method 600 begins at Block 610, at which, the controller 150 determines if the amplifier is starting up. In example operations, the host device 105 generates the enable signal (ENABLE) to turn on and off the audio amplifier 110. The stepping select circuitry 510 or, more generally, the controller 150 monitors the enable signal (ENABLE) for edges, which represent turn on or off events. For example, the stepping select circuitry 510 detects a turn on event of the audio amplifier 110 responsive to a rising edge of the enable signal (ENABLE). In such examples, the stepping select circuitry 510 initiates the soft stepping logic 530 for a start-up of the audio amplifier 110. If the controller 150 determines the amplifier is not starting up (e.g., Block 610 returns a result of NO), control proceeds to return to Block 610.

If the controller 150 determines the amplifier is starting up (e.g., Block 610 returns a result of YES), the audio modulation circuitry 125, the switch circuitry 135, 140, and the pulse circuitry 145 turn on the amplifier using soft-stepping. (Operations 700 of FIG. 7). In example operations, during start-up operations of the audio amplifier 110, the controller 150 sets the soft stepping control signal (SS_CNTRL) to initiate soft stepping operations. During soft stepping operations, the audio modulation circuitry 125, the switch circuitry 135, 140, and the pulse circuitry 145 implement soft stepping to gradually increase the pulse width of the amplified signals (OUTP, OUTM). The audio modulation circuitry 125, the switch circuitry 135, 140, and the pulse circuitry 145 complete the soft stepping operations when the duty cycle of the amplified signals (OUTP, OUTM) is, e.g., fifty percent.

The audio amplifier 110 receives an input signal. (Block 620). In example operations, after the audio modulation circuitry 125, the switch circuitry 135, 140, and the pulse circuitry 145 turn on the audio amplifier 110, the host device 105 may begin to provide audio signals (INP, INM) for audio playback operations. During such a time, the audio amplifier 110 receives the audio signals (INP, INM) representing audible soundwaves.

The audio modulation circuitry 125 modulates a carrier signal using the input signal. (Block 630). In example operations, the audio modulation circuitry 125 uses AD modulation to generate the modulated signals (MOD_OUTP, MOD_OUTM) from the audio signals (INP, INM). For example, during normal operations, the switch circuitry 230 provides the ramp signal (RAMP) to the comparator 250. In some such examples, the loop filter 210 and the comparators 240, 250 implement AD modulation by driving the modulated signals (MOD_OUTP, MOD_OUTM) to one of two states.

The output stage 155 drives an output using the modulated signal. (Block 640). In example normal operations, the switch circuitry 135, 140 provide the modulated signals (MOD_OUTP, MOD_OUTM) to the output stage 155. The output stage 155 amplifies the logic levels of the modulated signals (MOD_OUTP, MOD_OUTM) to produce the amplified signals (OUTP, OUTM).

The EMI filter circuitry 115 filters the output of the amplifier. (Block 650). In example operations, the EMI filter circuitry 115 filters frequencies outside a bandwidth of the audio amplifier 110 from the amplified signals (OUTP, OUTM). For example, if the audio amplifier 110 produces the amplified signals (OUTP, OUTM) using a two megahertz switching frequency (e.g., the frequency of the carrier signal), the EMI filter circuitry 115 filters signals having frequencies greater than two megahertz. In some embodiments, the EMI filter circuitry 115 advantageously improves signal integrity and playback of the audio.

The controller 150 determines if the amplifier is shutting down. (Block 660). In example operations, the host device 105 generates the enable signal (ENABLE) to turn on and off the audio amplifier 110. The stepping select circuitry 510 or, more generally, the controller 150 monitors the enable signal (ENABLE) for edges, which represent turn on or off events. For example, the stepping select circuitry 510 detects a turn off event of the audio amplifier 110 responsive to a falling edge of the enable signal (ENABLE). In such examples, the stepping select circuitry 510 initiates the soft stepping logic 530 for a shut-down of the audio amplifier 110. If the controller determines that the amplifier is not shutting down (e.g., Block 660 returns a result of NO), control proceeds to return to Block 620.

If the controller 150 determines that the amplifier is shutting down (e.g., Block 660 returns a result of YES), the pulse circuitry 145 turns off the amplifier using soft-stepping. (Operations 800 of FIG. 8). In the example operations 800, during shut-down operations of the audio amplifier 110, the controller 150 sets the soft stepping control signal (SS_CNTRL) to initiate soft stepping operations. During soft stepping operations, the audio modulation circuitry 125, the switch circuitry 135, 140, and the pulse circuitry 145 implement soft stepping to gradually decrease the pulse width of the amplified signals (OUTP, OUTM). The audio modulation circuitry 125, the switch circuitry 135, 140, and the pulse circuitry 145 complete the soft stepping operations when the duty cycle of the amplified signals (OUTP, OUTM) is approximately equal to a minimum duty cycle, which can be less than the minimum pulse width. Control proceeds to return to Block 610.

Although example methods are described with reference to the flowchart illustrated in FIG. 6, many other methods of implementing the audio amplifier 110 of FIG. 1 may alternatively be used in this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIG. 7 is a flowchart of embodiment method 700 for operating the audio modulation circuitry 125 of FIGS. 1 and 2, the pulse circuitry 145 of FIGS. 1 and 3, and the controller 150 of FIGS. 1 and 5 or, more generally, audio amplifier 110 of FIG. 1 according to an embodiment of the present disclosure. Method 700 begin at Block 705, at which, the audio amplifier 110 receives input signals. In example operations, the audio amplifier 110 receives the audio signals (INP, INM) from the host 105. During start-up operations, which is a period of time between setting the enable signal (ENABLE) and providing audio for playback, the host 105 sets the audio signals (INP, INM) to a common mode voltage. During such time, the host 105 allows the audio amplifier 110 to start-up without having audio to play.

The audio modulation circuitry 125 modulates carrier signals using the input signals and BD modulation. (Block 710). In example operations, during soft stepping, the soft stepping control signal (SS_CNTRL) sets the switch circuitry 230 to provide the inverted ramp signal (RAMP_Z) to the comparator 250. In such examples, the loop filter 210 and the comparators 240, 250 use BD modulation and the audio signals (INP, INM) to generate the modulated signals (MOD_OUTP, MOD_OUTM). Advantageously, BD modulation allows the comparators 240, 250 to set the differential output of the modulated signals (MOD_OUTP, MOD_OUTM) to three possible states (e.g., −1, 0, 1). During start-up operations, ideally, the comparators 240, 250 produce the modulated signals (MOD_OUTP, MOD_OUTM) with a fixed pulse width corresponding to, e.g., a fifty percent duty cycle. However, in reality, variations in process, temperature, noise, etc., produce differences between the edges of the modulated signals (MOD_OUTP, MOD_OUTM).

The conversion circuitry 300 or, more generally, the pulse circuitry 145 converts the modulated carrier signals to LSR modulated signals. (Block 715). In example operations, the conversion circuitry 300 subtracts the modulated signals (MOD_OUTP, MOD_OUTM) to produce the LSR modulated signals (LSR_MODP, LSR_MODM). During start-up operations, when the audio signals (INP, INM) are set to a common mode voltage, pulses of the LSR modulated signals (LSR_MODP, LSR_MODM) correspond to differences between the current paths of the respective modulated signals (MOD_OUTP, MOD_OUTM).

The pulse generator circuitry 303, 306 or, more generally, the pulse circuitry 145 sets a pulse width of pulses of the LSR modulated signals. (Block 720). In example operations, the pulse generator circuitry 303, 306 modify pulses of the LSR modulated signals (LSR_MODP, LSR_MODM) to have a pulse width corresponding to the pulse width signal (P_WIDTH). In some examples, such as FIGS. 3 and 4, the pulse generator circuitry 303, 306 use the delay cell circuitry 321 to delay edges of the LSR modulated signals (LSR_MODP, LSR_MODM). The pulse generator circuitry 303, 306 generate the adjusted pulse signals (DOUTP, DOUTM) having pulse(s) with a pulse width of the pulse width signal (P_WIDTH).

The threshold circuitry 560 or, more generally, the controller 150 determines if the pulse width is less than a minimum pulse width. (Block 725). In example operations, the threshold circuitry 560 compares the pulse width signal (P_WIDTH) and the pulse extension signal (P_EXTEND). The threshold circuitry 560 determines if the pulse widths of the adjusted pulse signals (DOUTP, DOUTM) are greater than a minimum pulse width corresponding to the pulse extension signal (P_EXTEND). In such example operations, the threshold circuitry 560 generates the minimum control signal (MIN_CNTRL) responsive to the comparison. The switch circuitry 309, 312 route the adjusted pulse signals (DOUTP, DOUTM) to one of the output stage 155 or the minimum pulse circuitry 315 responsive to the minimum control signal (MIN_CNTRL).

If the controller 150 determines the pulse width is less than the minimum pulse width (e.g., Block 725 returns a result of YES), the minimum pulse circuitry 315 or, more generally, the pulse circuitry 145 extends pulses of the LSR modulated signal by the minimum pulse width. (Block 730). In example operations, if the switch circuitry 309, 312 provide the adjusted pulse signals (DOUTP, DOUTM) to the minimum pulse circuitry 315, the pulse extension circuitry 351, 354 extend pulses of the adjusted pulse signals (DOUTP, DOUTM) by the pulse width corresponding to the pulse extension signal (P_EXTEND).

The pulse extension circuitry 351, 354 or, more generally, the pulse circuitry 145 add pulses having the minimum pulse width to the LSR modulated signals based on the extended pulses. (Block 735). In some examples simultaneous to Block 730, the pulse extension circuitry 351, 354 may add a pulse having the pulse width of the pulse extension signal (P_EXTEND) to the one of the adjusted pulse signals (DOUTP, DOUTM) without the extended pulse. In such example operations, the pulse extension circuitry 351, 354 may prevent pulses having a pulse width less than the minimum pulse width of the pulse extension signal (P_EXTEND) from being supplied to the output stage 155.

Advantageously, the pulse extension and addition of the pulse extension circuitry 351, 354 differentially cancel at the output stage to produce an effective pulse having the pulse width corresponding to the pulse width signal (P_WIDTH). In some embodiments, the minimum pulse circuitry 315 advantageously prevents pulses below the minimum pulse width of the pulse extension signal (P_EXTEND) from switching the output stage 155 at a speed faster than a supported bandwidth.

If the controller 150 determines the pulse width is not less than the minimum pulse width (e.g., Block 725 returns a result of NO) or control proceeds from Block 735, the pulse generator circuitry 303, 306 or, more generally, the pulse circuitry 145 drives an output using the LSR modulated signals. (Block 740). In example operations, the pulse circuitry 145 provides the soft stepping signals (SS_OUTP, SS_OUTM) having adjusted pulse widths corresponding to the pulse width signal (P_WIDTH). In some such example operations, the output stage 155 generates the amplified signals (OUTP, OUTM) having pulse widths of the soft stepping signals (SS_OUTP, SS_OUTM).

The pulse width circuitry 540 or, more generally, the controller 150 determines if the pulse width is ready to increase. (Block 745). In example operations, the pulse width circuitry 540 increments the pulse width signal (P_WIDTH) by a step increment after a step duration. In some examples, the soft stepping logic 530 provides the step increment and step duration. In some such example operations, the pulse width circuitry 540 steps up (e.g., monotonically increases, increases in increments, etc.) the pulse width signal (P_WIDTH) from an initial pulse width until a final pulse width. In some examples, the soft stepping logic 530 provides the initial and final pulse width. In other examples, the pulse width circuitry 540 uses predetermined step increment, step duration, initial pulse width, and final pulse width.

In either example, during soft stepping turn on, the initial pulse width corresponds to, e.g., a five percent duty cycle, the final pulse width corresponds to, e.g., a fifty percent duty cycle, the step increment corresponds to, e.g., a five percent duty cycle increase, and the step duration corresponds to, e.g., ten pulses. In some such examples, the pulse width circuitry 540 determines to change the pulse width signal (P_WIDTH) using the step duration.

If the controller 150 determines that the pulse width is ready to increase (e.g., Block 745 returns a result of YES), the pulse generator circuitry 303, 306 or, more generally, the pulse circuitry 145 increases the pulse width of the LSR modulated signals. (Block 750). In example operations, after the controller 150 increments the pulse width signal (P_WIDTH) by the step increment, the pulse generator circuitry 303, 306 adjust pulse widths of the LSR modulated signals (LSR_MODP, LSR_MODM). In such example operations, the pulse generator circuitry 303, 306 generate the adjusted pulse signals (OUTP, OUTM) to have pulse widths corresponding to the pulse width signal (P_WIDTH).

The soft stepping circuitry 530 or, more generally, the controller 150 determines if a duty cycle of the modulated signals is greater than or equal to a threshold. (Block 755). In example operations to start up the audio amplifier 110, the soft stepping circuitry 530 compares a current pulse width of the pulse width circuitry 540 to a threshold duty cycle. In some examples, the threshold duty cycle is the end pulse width provided to the pulse width circuitry 540. For example, during start-up operations, the soft stepping circuitry 530 monitors the pulse width circuitry 540 for a pulse width corresponding to a fifty percent duty cycle. If the pulse width is less than the threshold, the soft stepping circuitry 530 determines to keep the soft stepping control signal (SS_CNTRL) asserted and to continue soft stepping operations.

If the controller 150 determines that the duty cycle of the modulated signals is not greater than or equal to the threshold (e.g., Block 755 returns a result of NO) or determines the pulse width is not ready to increase (e.g., Block 745 returns a result of NO), control proceeds to Block 725. In example operations, the soft stepping control signal (SS_CNTRL) keeps the audio modulation circuitry 125, the switch circuitry 135, 140, and the pulse circuitry 145 set for soft stepping operations.

If the controller 150 determines that the duty cycle of the modulated signals is greater than or equal to the threshold (e.g., Block 755 returns a result of YES), the audio modulation circuitry 125 swaps to AD modulation. (Block 760). In some examples, the soft stepping circuitry 530 deasserts the soft stepping control signal (SS_CNTRL) responsive to a determination that the pulse width circuitry 540 has stepped the pulse width signal (P_WIDTH) to the end pulse width. In example operations, the soft stepping control signal (SS_CNTRL) toggles the switch circuitry 230 to provide the ramp signal (RAMP) as a carrier signal to the comparator 250. In some such example operations, the comparators 240, 250 are structured to generate the modulated signals (MOD_OUTP, MOD_OUTM) using AD modulation. Also, the soft stepping control signal (SS_CNTRL) toggles the switch circuitry 135, 140 to provide the modulated signals (MOD_OUTP, MOD_OUTM) to the output stage 155. Advantageously, during the operations of Block 760, the pulse circuitry 145 can stop adjusting the pulse width signal (P_WIDTH). Advantageously, after soft stepping operations, the audio amplifier 110 implements AD modulation to modulate the audio signals (INP, INM) for playback on the speaker 120.

Control proceeds to return. Advantageously, after soft stepping operations, the audio amplifier 110 implements AD modulation to modulate the audio signals (INP, INM) for playback on the speaker 120. Advantageously, in comparison to BD modulation, AD modulation has a relatively lower noise distortion, which improves playback performance of the audio amplifier 110.

Although example methods are described with reference to the flowchart illustrated in FIG. 7, many other methods of implementing the audio modulation circuitry 125 of FIGS. 1 and 2, the pulse circuitry 145 of FIGS. 1 and 3, and the controller 150 of FIGS. 1 and 5 or, more generally, audio amplifier 110 of FIG. 1 may alternatively be used in this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIG. 8 is a flowchart of embodiment method 800 for operating the audio modulation circuitry 125 of FIGS. 1 and 2, the pulse circuitry 145 of FIGS. 1 and 3, and the controller 150 of FIGS. 1 and 5 or, more generally, audio amplifier 110 of FIG. 1, according to an embodiment of the present disclosure. Method 800 begins at Block 805, at which, the audio amplifier 110 receives input signals. In example operations, the audio amplifier 110 receives the audio signals (INP, INM) from the host 105. During shut down operations, which is a period of time after deasserting the enable signal (ENABLE), the host 105 sets the audio signals (INP, INM) to a common mode voltage. During such time, the host 105 allows the audio amplifier 110 to shut down without having audio to play.

The audio modulation circuitry 125 modulates carrier signals using the input signals and BD modulation. (Block 810). In example operations, during soft stepping, the soft stepping control signal (SS_CNTRL) sets the switch circuitry 230 to provide the inverted ramp signal (RAMP_Z) to the comparator 250. In such examples, the loop filter 210 and the comparators 240, 250 use BD modulation and the audio signals (INP, INM) to generate the modulated signals (MOD_OUTP, MOD_OUTM). During shut-down operations, ideally, the comparators 240, 250 produce the modulated signals (MOD_OUTP, MOD_OUTM) with a fixed pulse width corresponding to approximately a fifty percent duty cycle. Variations in process, temperature, noise, etc., may produce differences between the edges of the modulated signals (MOD_OUTP, MOD_OUTM).

The conversion circuitry 300 or, more generally, the pulse circuitry 145 converts the modulated carrier signals to LSR modulated signals. (Block 815). In example operations, the conversion circuitry 300 subtracts the modulated signals (MOD_OUTP, MOD_OUTM) to produce the LSR modulated signals (LSR_MODP, LSR_MODM). During shut-down operations, when the audio signals (INP, INM) are set to a common mode voltage, pulses of the LSR modulated signals (LSR_MODP, LSR_MODM) correspond to differences between the current paths of the respective modulated signals (MOD_OUTP, MOD_OUTM).

The pulse generator circuitry 303, 306 or, more generally, the pulse circuitry 145 sets a pulse width of pulses of the LSR modulated signals. (Block 820). In example operations, the pulse generator circuitry 303, 306 modify pulses of the LSR modulated signals (LSR_MODP, LSR_MODM) to have a pulse width corresponding to the pulse width signal (P_WIDTH). In some examples, such as FIGS. 3 and 4, the pulse generator circuitry 303, 306 use the delay cell circuitry 321 to delay edges of the LSR modulated signals (LSR_MODP, LSR_MODM). The pulse generator circuitry 303, 306 generate the adjusted pulse signals (DOUTP, DOUTM) having pulse(s) with a pulse width of the pulse width signal (P_WIDTH).

The threshold circuitry 560 or, more generally, the controller 150 determines if the pulse width is less than a minimum pulse width. (Block 825). In example operations, the threshold circuitry 560 compares the pulse width signal (P_WIDTH) and the pulse extension signal (P_EXTEND). The threshold circuitry 560 determines if the pulse widths of the adjusted pulse signals (DOUTP, DOUTM) are greater than a minimum pulse width corresponding to the pulse extension signal (P_EXTEND). In such example operations, the threshold circuitry 560 generates the minimum control signal (MIN_CNTRL) responsive to the comparison. The switch circuitry 309, 312 route the adjusted pulse signals (DOUTP, DOUTM) to one of the output stage 155 or the minimum pulse circuitry 315 responsive to the minimum control signal (MIN_CNTRL).

If the controller 150 determines that the pulse width is less than the minimum pulse width (e.g., Block 825 returns a result of YES), the minimum pulse circuitry 315 or, more generally, the pulse circuitry 145 extends pulses of the LSR modulated signal by the minimum pulse width. (Block 830). In example operations, if the switch circuitry 309, 312 provide the adjusted pulse signals (DOUTP, DOUTM) to the minimum pulse circuitry 315, the pulse extension circuitry 351, 354 extend pulses of the adjusted pulse signals (DOUTP, DOUTM) by the pulse width corresponding to the pulse extension signal (P_EXTEND).

The pulse extension circuitry 351, 354 or, more generally, the pulse circuitry 145 adds pulses having the minimum pulse width to the LSR modulated signals based on the extended pulses. (Block 835). In some examples simultaneous to Block 730, the pulse extension circuitry 351, 354 add a pulse having the pulse width of the pulse extension signal (P_EXTEND) to the one of the adjusted pulse signals (DOUTP, DOUTM) without the extended pulse. In such example operations, the pulse extension circuitry 351, 354 prevent pulses having a pulse width less than the minimum pulse width of the pulse extension signal (P_EXTEND) from being supplied to the output stage 155.

Advantageously, the pulse extension and addition of the pulse extension circuitry 351, 354 differentially cancel at the output stage to produce an effective pulse having the pulse width corresponding to the pulse width signal (P_WIDTH). Advantageously, the minimum pulse circuitry 315 prevents pulses below the minimum pulse width of the pulse extension signal (P_EXTEND) from switching the output stage 155 at a speed faster than a supported bandwidth.

If the controller 150 determines that the pulse width is greater than the minimum pulse width (e.g., Block 825 returns a result of NO) or control proceeds from Block 835, the pulse generator circuitry 303, 306 or, more generally, the pulse circuitry 145 drives an output using the LSR modulated signals. (Block 840). In example operations, the pulse circuitry 145 provides the soft stepping signals (SS_OUTP, SS_OUTM) having adjusted pulse widths corresponding to the pulse width signal (P_WIDTH). In some such example operations, the output stage 155 generates the amplified signals (OUTP, OUTM) having pulse widths of the soft stepping signals (SS_OUTP, SS_OUTM).

The soft stepping circuitry 530 or, more generally, the controller 150 determines if the pulse width is ready to decrease. (Block 845). In example operations, the pulse width circuitry 540 decrements the pulse width signal (P_WIDTH) by a step decrement (e.g., a set percentage or duration of time) after a step duration. In some examples, the soft stepping logic 530 provides the step decrement and step duration. In some such examples, the pulse width circuitry 540 steps down the pulse width signal (P_WIDTH) from an initial pulse width until a final pulse width. In some examples, the soft stepping logic 530 provides the initial and final pulse width. In other examples, the pulse width circuitry 540 uses predetermined step decrement, step duration, initial pulse width, and final pulse width.

In either example, during soft stepping shut down, the initial pulse width corresponds to a fifty percent duty cycle, the final pulse width corresponds to a five percent duty cycle, the step decrement corresponds to a five percent duty cycle decrease, and the step duration corresponds to ten pulses. In some such examples, the pulse width circuitry 540 determines to change the pulse width signal (P_WIDTH) using the step duration.

If the controller 150 determines that the pulse width is ready to decrease (e.g., Block 845 returns a result of YES), the pulse generator circuitry 303, 306 or, more generally, the pulse circuitry 145 decreases the pulse width of the LSR modulated signals. (Block 850). In example operations, after the controller 150 decreases the pulse width signal (P_WIDTH) by the step decrement, the pulse generator circuitry 303, 306 adjust pulse widths of the LSR modulated signals (LSR_MODP, LSR_MODM). In such example operations, the pulse generator circuitry 303, 306 generate the adjusted pulse signals (OUTP, OUTM) to have pulse widths corresponding to the pulse width signal (P_WIDTH).

The soft stepping circuitry 530 or, more generally, the controller 150 determines if a duty cycle of the LSR modulated signals is less than or equal to a threshold. (Block 855). In example operations to shut-down the audio amplifier 110, the soft stepping circuitry 530 compares a current pulse width of the pulse width circuitry 540 to a threshold duty cycle. In some examples, the threshold duty cycle is the end pulse width provided to the pulse width circuitry 540. For example, during shut-down operations, the soft stepping circuitry 530 monitors the pulse width circuitry 540 for a pulse width corresponding to a five percent duty cycle. If the pulse width is less than the threshold, the soft stepping circuitry 530 determines to keep the soft stepping control signal (SS_CNTRL) asserted and to continue soft stepping operations.

If the controller 150 determines the duty cycle of the LSR modulated signals is greater than the threshold (e.g., Block 855 returns a result of NO) or determines the pulse width is not ready to decrease (e.g., Block 845 returns a result of NO), control proceeds to return to Block 825. In example operations, the soft stepping control signal (SS_CNTRL) keeps the audio modulation circuitry 125, the switch circuitry 135, 140, and the pulse circuitry 145 set for soft stepping operations.

If the controller 150 determines the duty cycle of the LSR modulated signals is greater than the threshold (e.g., Block 855 returns a result of YES), the audio modulation circuitry 125 swaps to AD modulation. (Block 860). In some examples, the soft stepping circuitry 530 deasserts the soft stepping control signal (SS_CNTRL) responsive to a determination that the pulse width circuitry 540 has stepped the pulse width signal (P_WIDTH) to the end pulse width. In example operations, the soft stepping control signal (SS_CNTRL) toggles the switch circuitry 230 to provide the ramp signal (RAMP) as a carrier signal to the comparator 250. In some such example operations, the comparators 240, 250 are structured to generate the modulated signals (MOD_OUTP, MOD_OUTM) using AD modulation. Also, the soft stepping control signal (SS_CNTRL) toggles the switch circuitry 135, 140 to provide the modulated signals (MOD_OUTP, MOD_OUTM) to the output stage 155.

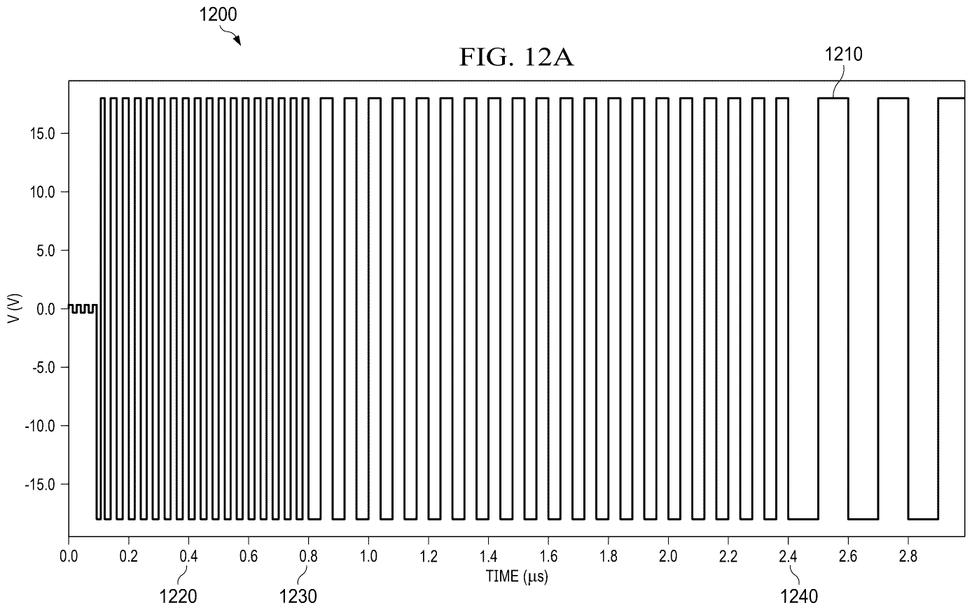

Control proceeds from Block 860 to return to the operations 600 of FIG. 6. Advantageously, the audio amplifier 110 may use soft stepping to slowly step down the pulse width of the amplified signals (OUTP, OUTM) during shut-down operations. Advantageously, slowly stepping down the pulse width of the amplified signals (OUTP, OUTM) decreases a transient voltage of the speaker 120 during shutdown. For example, without soft stepping the pulse width of the amplified signals (OUTP, OUTM) decreases from approximately a fifty percent duty cycle to approximately zero, which produces a transient voltage and an audible crack or pop sound. Advantageously, with soft stepping, the pulse width of the amplified signals (OUTP, OUTM) decreases from the end pulse width (e.g., five percent duty cycle) to approximately zero, which produces a substantially smaller transient voltage (illustrated in FIG. 11). Advantageously, the substantially smaller transient voltage of the audio amplifier 110 decreases the likelihood of producing an audible crack or pop sound.

Although example methods are described with reference to the flowchart illustrated in FIG. 8, many other methods of implementing the audio modulation circuitry 125 of FIGS. 1 and 2, the pulse circuitry 145 of FIGS. 1 and 3, and the controller 150 of FIGS. 1 and 5 or, more generally, audio amplifier 110 of FIG. 1 may alternatively be used in this description. For example, the order of execution of the blocks may be changed, and/or some of the blocks described may be changed, eliminated, or combined. Similarly, additional operations may be included in the manufacturing process before, in between, or after the blocks shown in the illustrated examples.

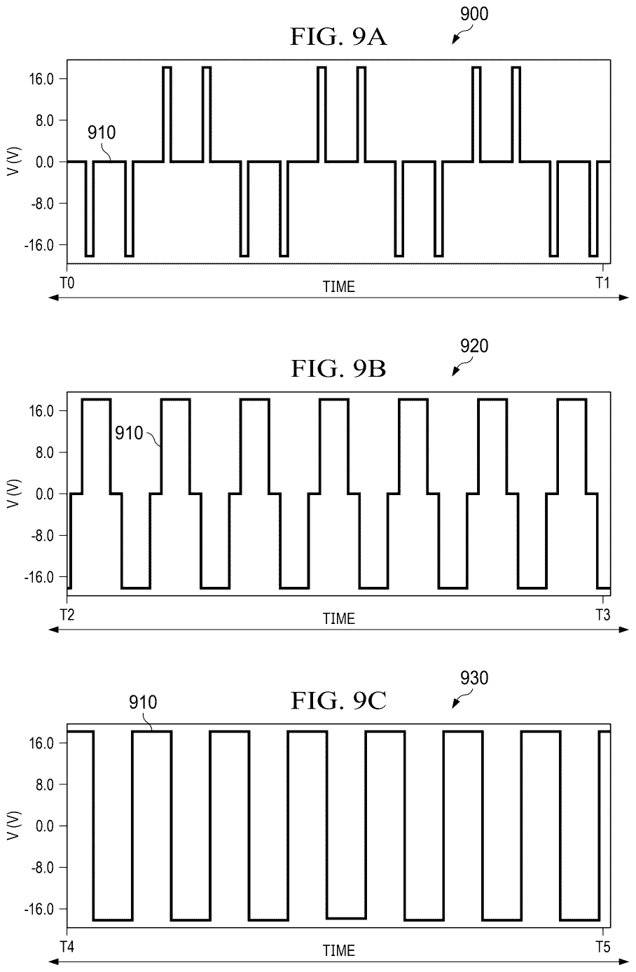

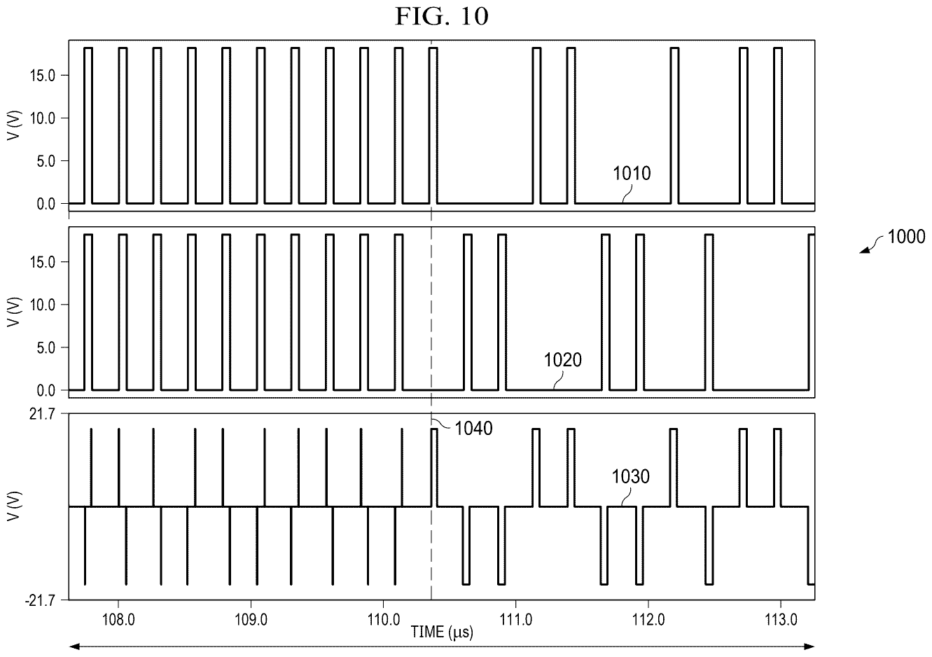

FIG. 9A is a timing diagram 900 of example operations of the audio amplifier 110 of FIG. 1. The example timing diagram 900 of FIG. 9A illustrates an amplifier output 910 during a first period of time (T0-T1). The amplifier output 910 represents the differential voltage of the amplified signals (OUTP, OUTM). In the example period of time illustrated by the timing diagram 900, the audio amplifier 110 begins soft stepping operations for turning on by setting the pulse widths of the amplified signals (OUTP, OUTM) to approximately a five percent duty cycle. For example, periodic pulses of the amplifier output 910 are approximately equal to a five percent duty cycle.

FIG. 9B is a timing diagram 920 of example operations of the audio amplifier 110 of FIG. 1. The example timing diagram 920 of FIG. 9B illustrates the amplifier output 910 during a second period of time (T2-T3), which occurs after the first period of time (T0-T1) of FIG. 9A. Between the time periods of the timing diagrams 900, 920, the audio amplifier 110 steps up the pulse widths of the amplified signals (OUTP, OUTM). In the example period of time illustrated by the timing diagram 920, the audio amplifier 110 continues soft stepping operations for turning on by setting the pulse widths of the amplifier output 910 to approximately a thirty percent duty cycle. In some examples, the audio amplifier 110 has several pulse width steps between the times of the timing diagrams 900, 920. For example, if the step increment corresponds to a five percent increase in duty cycle, the audio amplifier 110 has four steps (e.g., ten, fifteen, twenty, and twenty-five) between the times of the timing diagrams 900, 920.

FIG. 9C is a timing diagram 930 of example operations of the audio amplifier 110 of FIG. 1. The example timing diagram 930 of FIG. 9C illustrates the amplifier output 910 during a third period of time (T4-T5), which occurs after the times (T0-T3) of FIGS. 9A and 9B. Between the time periods of the timing diagrams 920, 930, the audio amplifier 110 further steps up the pulse widths of the amplifier output 910. In the example period of time illustrated by the timing diagram 930, the audio amplifier 110 completes soft stepping operations for turning on by setting the pulse widths of the amplifier output 910 to approximately a fifty percent duty cycle. In some examples, the audio amplifier 110 has several pulse width steps between the times of the timing diagrams 920, 930. For example, if the step increment corresponds to a five percent increase in duty cycle, the audio amplifier 110 has three steps (e.g., thirty-five, forty, and forty-five) between the times of the timing diagrams 920, 930. After the time (T5), the audio amplifier 110 begins normal operations, in which the host 105 provides audio for playback.

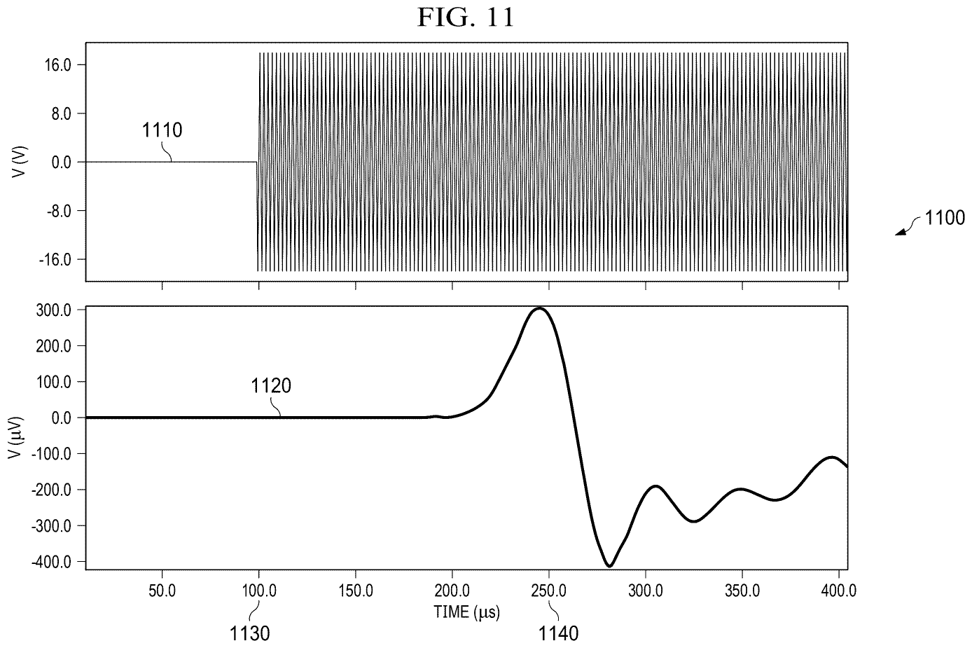

FIG. 10 is a timing diagram 1000 of example operations of the pulse circuitry 145 of FIGS. 1 and 3 or, more generally, audio amplifier 110 of FIG. 1. The example timing diagram 1000 of FIG. 10 illustrates a first amplified signal 1010 (OUTP), a second amplified signal 1020 (OUTM), and an amplifier output 1030 during example pulse soft-stepping. The amplified signals 1010, 1020 represent the amplified signals (OUTP, OUTM) from the output stage 155 or, more generally, at the output of the audio amplifier 110. The amplifier output 1030 represents the differential voltage of the amplified signals 1010, 1020.

Prior to time 1040, the pulse width signal (P_WIDTH) corresponds to a pulse width less than the minimum pulse width corresponding to the pulse extension signal (P_EXTEND). In such example operations, prior to the time 1040, the pulse circuitry 145 extends and adds pulses to the amplified signals 1010, 1020 using the pulse extension signal (P_EXTEND). For example, if the amplifier output 1030 has a negative pulse, the pulse extension circuitry 354 and the logic devices 357, 360 add a pulse to the amplified signal 1010 and extends a pulse of the amplified signal 1020. In some such example operations, the amplified signals 1010, 1020 differentially produce a pulse having a pulse width of the pulse width signal (P_WIDTH).

After time 1040, the pulse width signal (P_WIDTH) represents a pulse width that is approximately equal to the minimum pulse width of the pulse extension signal (P_EXTENSION). At approximately the time 1040, the switch circuitry 309, 312 begin to route the adjusted pulse signals (OUTP, OUTM), which have pulse widths set by the pulse width signal (P_WIDTH), to the output stage 155.

Advantageously, after the pulse width signal (P_WIDTH) is greater than or equal to the pulse extension signal (P_EXTEND), the minimum pulse circuitry 315 no longer adds and extends pulses of the soft switching signals (SS_OUTP, SS_OUTM). Advantageously, extending and adding pulses of the amplified signals 1010, 1020 prevent switching in the output stage 155 at speeds faster than the minimum pulse width of the pulse extension signal (P_EXTEND).

FIG. 11 is a timing diagram 1100 of example operations of the audio amplifier 110 of FIG. 1 during soft-stepping operations. The example timing diagram 1100 of FIG. 11 illustrates an example amplifier output 1110 and an example filtered amplifier output 1120. The amplifier output 1110 represents the differential voltage of the amplified signals (OUTP, OUTM) at the output of the audio amplifier 110. The filtered amplifier output 1120 represents a low pass filtered voltage of the amplifier output 1110, which represents audible sound.

At time 1130, the audio amplifier 110 begins soft stepping operations to prepare for audio playback. At time 1140, the filtered amplifier output 1120 has a transient voltage responsive to the turn on of the audio amplifier 110. At the time 1140, the transient voltage of the filtered amplifier output 1120 peaks at approximately three-hundred microvolts (μV). In comparison, without the soft stepping operations, turning on the audio amplifier 110 produces a transient voltage with a peak of approximately fifty-eight millivolts (mV). Advantageously, using soft stepping operations to turn on the audio amplifier 110 substantially reduces the audible crack or pop sound. Advantageously, using soft stepping operations to turn off the audio amplifier 110 also reduces the audible crack or pop sound.

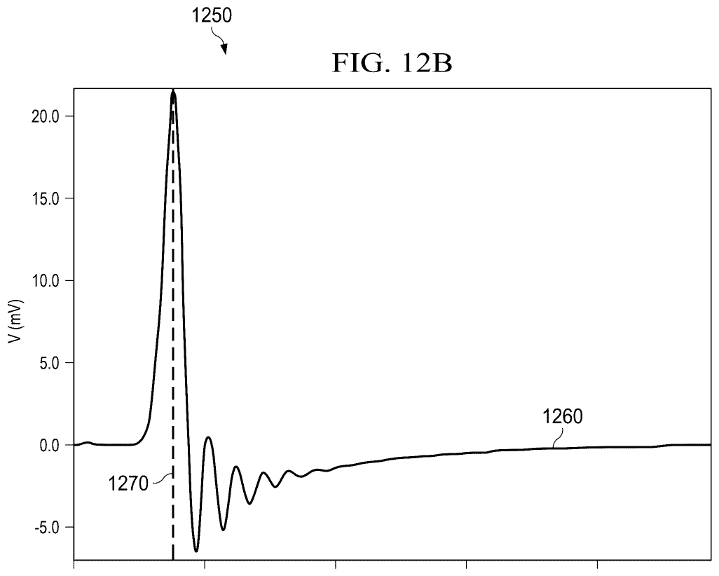

FIG. 12A is a timing diagram 1200 of example operations of the audio modulation circuitry 125 of FIGS. 1 and 2 or, more generally, the audio amplifier 110 of FIG. 1 during frequency stepping operations. In the example of FIG. 12A, the timing diagram 1200 illustrates an example amplifier output 1210 during frequency stepping operations. The amplifier output 1210 represents the differential voltage of the amplified signals (OUTP, OUTM) at the output of the audio amplifier 110.

Unlike in the examples of FIGS. 9A-11, in the example of FIGS. 12A and 12B, the controller 150 implements frequency stepping operations to turn on the audio amplifier 110. During frequency stepping operations, the controller 150 decreases, in steps, the frequency of the clock circuitry 130, which provides the reference clock (CLK). In example operations, the carrier signal generator 220 generates the ramp signal (RAMP) as a carrier signal having a frequency matching that of the reference clock (CLK). In some such examples, decreasing the frequency of the reference clock (CLK) from an initially high frequency to a final lower frequency.

At relatively high frequencies of the reference and ramp signals (CLK, RAMP), such as at time 1220, the audio modulation circuitry 125 uses AD modulation to produce the modulated signals (MOD_OUTP, MOD_OUTM) having a fifty percent duty cycle and relatively short pulse widths. Accordingly, the amplifier output 1210 initially has relatively short pulse widths and a fifty percent duty cycle. As the controller 150 decreases the frequency of the reference and ramp signals (CLK, RAMP), such as between times 1220, 1230, 1240, the pulse widths of the amplifier output 1210 increase. The controller 150 completes frequency stepping operation once the frequency of the reference and ramp signals (CLK, RAMP) are at a target frequency. In some examples, the target frequency is referred to as a switching frequency, which corresponds to playback operations of the audio amplifier 110, such as a frequency of approximately two megahertz (MHz). Advantageously, during frequency stepping operations, periodic pulses of the amplifier output 1210 have a varying pulse width and maintaining a fixed duty cycle. Advantageously, the increasing pulse width during frequency stepping operations is similar to the increasing pulse width during soft stepping operations.

FIG. 12B is a timing diagram 1250 of example operations of the audio modulation circuitry 125 of FIGS. 1 and 2 or, more generally, the audio amplifier 110 of FIG. 1 during frequency stepping operations. The example timing diagram 1250 of FIG. 12B illustrates an example filtered amplifier output 1260 during frequency stepping operations. The filtered amplifier output 1260 represents a low pass filtered voltage of the amplifier output 1210, which represents audible sound. The timing diagram 1250 illustrates a transient voltage produced by the audio amplifier 110 during the frequency stepping operations of FIG. 12A. At time 1270, the peak voltage of the filtered amplifier output 1260 is approximately twenty-one millivolts (mV). In comparison, without the frequency stepping operations, turning on the audio amplifier 110 produces a transient voltage with a peak of approximately fifty-eight millivolts (mV). Advantageously, using frequency stepping operations to turn on the audio amplifier 110 substantially reduces the audible crack or pop sound. Advantageously, using frequency stepping operations to turn off the audio amplifier 110 also reduces the audible crack or pop sound.

Example embodiments of the present disclosure are summarized here. Other embodiments can also be understood from the entirety of the specification and the claims filed herein.

Example 1. A device including: modulation circuitry; switch circuitry having a first terminal, a second terminal, and a third terminal, the first terminal of the switch circuitry coupled to the modulation circuitry; pulse circuitry having a first terminal and a second terminal, the first terminal of the pulse circuitry coupled to the second terminal of the switch circuitry; and an output stage coupled to the third terminal of the switch circuitry and the second terminal of the pulse circuitry.

Example 2. The device of example 1, where the switch circuitry is first switch circuitry, and the modulation circuitry includes: loop filter circuitry having a terminal; a signal generator having an inverting terminal and a non-inverting terminal; second switch circuitry having a first terminal, a second terminal, and a third terminal, the first terminal of the second switch circuitry coupled to the inverting terminal of the signal generator, the second terminal of the second switch circuitry coupled to the non-inverting terminal of the signal generator; and a comparator having a first terminal coupled to the terminal of the loop filter circuitry, a second terminal coupled to the third terminal of the second switch circuitry, and a third terminal coupled to the first terminal of the first switch circuitry.

Example 3. The device of one of examples 1 or 2, where the terminal of the loop filter circuitry is a first terminal, the loop filter circuitry further having a second terminal, the comparator is a first comparator, and the modulation circuitry further includes a second comparator having a first terminal coupled to the second terminal of the loop filter circuitry, a second terminal coupled to the non-inverting terminal of the signal generator and the second terminal of the second switch circuitry, and a third terminal coupled to the output stage.

Example 4. The device of one of examples 1 to 3, where the switch circuitry is first switch circuitry, and the pulse circuitry includes: conversion logic having a first terminal and a second terminal, the first terminal of the conversion logic coupled to the second terminal of the first switch circuitry; pulse generator circuitry having an a first terminal and a second terminal, the first terminal coupled to the second terminal of the conversion logic; second switch circuitry having a first terminal, a second terminal, and a third terminal, the first terminal of the second switch circuitry coupled to the second terminal of the pulse generator circuitry; and minimum pulse circuitry having a first terminal and a second terminal, the first terminal of the minimum pulse circuitry coupled to the second terminal of the second switch circuitry, the second terminal of the minimum pulse circuitry coupled to the output stage and the third terminal of the second switch circuitry.

Example 5. The device of one of examples 1 to 4, where the pulse generator circuitry includes: pulse adder circuitry having a first terminal, a second terminal, a third terminal, and a fourth terminal, the first terminal of the pulse adder circuitry coupled to the first terminal of the second switch circuitry; a delay cell having a first terminal and a second terminal, the first terminal of the delay cell coupled to the second terminal of the pulse adder circuitry; and a logic device having a first terminal coupled to the second terminal of the conversion logic and the third terminal of the pulse adder circuitry, a second terminal coupled to the second terminal of the delay cell, and a third terminal coupled to the fourth terminal of the pulse adder circuitry.

Example 6. The device of one of examples 1 to 5, where the logic device is a first logic device, and the pulse adder circuitry includes: a multiplexer having a first terminal, a second terminal, and a control terminal; a first inverter having a first terminal and a second terminal, the first terminal of the first inverter coupled to the second terminal of the multiplexer; a latch having a first terminal, a second terminal, and a third terminal, the first terminal of the latch coupled to the second terminal of the conversion logic and the first terminal of the multiplexer, the second terminal of the latch coupled to the second terminal of the first inverter; a second logic device having a first terminal and a second terminal, the first terminal of the second logic device coupled to the first terminal of the second switch circuitry and the third terminal of the latch; and a second inverter having a first terminal coupled to the control terminal of the multiplexer and a second terminal coupled to the first terminal of the delay cell and the second terminal of the second logic device.

Example 7. The device of one of examples 1 to 6, where the minimum pulse circuitry includes: first pulse adder circuitry having a first terminal, a second terminal, a third terminal and a fourth terminal, the first terminal of the first pulse adder circuitry coupled to the output stage; a first delay cell having a first terminal and a second terminal, the first terminal of the first delay cell coupled to the second terminal of the first pulse adder circuitry; a first logic device having a first terminal, a second terminal, and a third terminal, the first terminal of the first logic device coupled to the second terminal of the first delay cell; an inverter having a first terminal and a second terminal, the first terminal of the inverter coupled to the second terminal of the second switch circuitry, the third terminal of the first pulse adder circuitry, and the second terminal of the first logic device; second pulse adder circuitry having a first terminal, a second terminal, and a third terminal, the first terminal of the second pulse adder circuitry coupled to the second terminal of the inverter; a second delay cell having a first terminal and a second terminal, the first terminal of the second delay cell coupled to the second terminal of the second pulse adder circuitry; and a second logic device having a first terminal coupled to the third terminal of the first logic device, a second terminal coupled to the third terminal of the second pulse adder circuitry and the second terminal of the second delay cell, and a third terminal coupled to the fourth terminal of the first pulse adder circuitry.

Example 8. The device of one of examples 1 to 7, where the switch circuitry further has a control terminal, the pulse circuitry further has a third terminal, and the device further including: clock circuitry having a first terminal and a second terminal, the first terminal of the clock circuitry coupled to the modulation circuitry; and a controller having a first terminal coupled to the second terminal of the clock circuitry, a second terminal coupled to the modulation circuitry and the control terminal of the switch circuitry, and a third terminal coupled to the third terminal of the pulse circuitry.

Example 9. The device of one of examples 1 to 8, where the controller includes: stepping select logic; frequency stepping logic coupled to the stepping select logic and the clock circuitry; soft stepping logic coupled to the stepping select logic and the control terminal of the switch circuitry; and pulse width logic coupled to the soft stepping logic and the pulse circuitry.

Example 10. A device including: modulation circuitry capable of modulating audio signals to generate differential signals; and pulse circuitry coupled to the modulation circuitry, the pulse circuitry capable of: adjusting a pulse width of periodic pulses of the differential signals; setting outputs using the differential signals; increasing the pulse width of the periodic pulses across a plurality of cycles of the differential signals; and after a determination that the pulse width is greater than or equal to a threshold pulse width, stop adjusting the pulse width of the differential signals.

Example 11. The device of example 10, where increasing the pulse width of periodic pulses includes increasing the pulse width of the periodic pulses while maintaining a fixed duty cycle of the periodic pulses.

Example 12. The device of one of examples 10 or 11, the modulation circuitry further capable of: receiving a stepping control signal; when the stepping control signal is asserted, generating the differential signals using a first class of modulation; and when the stepping control signal is deasserted, generating the differential signals using a second class of modulation.

Example 13. The device of one of examples 10 to 12, where the first class of modulation is AD modulation and the second class of modulation is BD modulation.

Example 14. The device of one of examples 10 to 13, where the pulse circuitry is further capable of: converting the differential signals from a first class of modulation to a second class of modulation; and setting the pulse width of the periodic pulses of the converted signals.

Example 15. The device of one of examples 10 to 14, where the pulse circuitry is further capable of: extending a pulse of a first one of the differential signals by a minimum pulse width; and adding a pulse having the minimum pulse width to a second one of the differential signals.

Example 16. The device of one of examples 10 to 15, further including: clock circuitry coupled to the modulation circuitry, the clock circuitry capable of setting a frequency of the differential signals using a clock signal; and a controller coupled to the clock circuitry, the controller capable of controlling the frequency of the clock signal.

Example 17. The device of one of examples 10 to 16, the controller capable of: setting a frequency of the differential signals to a first frequency; decreasing the frequency of the differential signals; and after a determination that the frequency of the differential signals is less than or equal to a threshold frequency, stop adjusting the frequency of the differential signals, the threshold frequency corresponding to the threshold pulse width.

Example 18. The device of one of examples 10 to 17, further including: an output stage; and switch circuitry coupled to the modulation circuitry, the pulse circuitry, and the output stage, the switch circuitry capable of providing the differential signals to one of the pulse circuitry or the output stage.

Example 19. The device of one of examples 10 to 18, further including a controller coupled to the modulation circuitry, the pulse circuitry, and the switch circuitry, the controller capable of: adjusting the modulation circuitry to use a first class of modulation; after adjusting the modulation circuitry, adjusting the switch circuitry to provide the differential signals to the pulse circuitry; and after the determination that the pulse width is greater than or equal to the threshold pulse width, adjusting the modulation circuitry to use a second class of modulation and adjusting the switch circuitry to provide the differential signals to the output stage.

Example 20. The device of one of examples 10 to 19, where the pulse circuitry is further capable of: after a determination to turn off the device, decreasing the pulse width of the periodic pulses across a plurality of cycles of the differential signals; and after a determination that the pulse width is less than or equal to a minimum pulse width, stop adjusting the pulse width of the differential signals.

Example 21. A method including: receiving an audio signal; modulating the audio signal to produce a modulated signal having a pulse width; setting the pulse width of the modulated signal to a minimum pulse width; providing the modulated signal having the minimum pulse width to a speaker; after providing the modulated signal to the speaker, monotonically increasing the pulse width of the modulated signal; and after the pulse width of the modulated signal is greater than or equal to a threshold, playing audio of the audio signal using the speaker.

Example 22. The method of example 21, further including: determining a state of the audio signal; and after determining the state of the audio signal is idle, decreasing the pulse width of the modulated signal by a set percentage.

Example 23. The method of one of examples 21 or 22, where monotonically increasing the pulse width of the modulated signal includes monotonically increasing the pulse width of the modulated signal by a set percentage.

Example 24. The method of one of examples 21 to 23, where monotonically increasing the pulse width of the modulated signal includes monotonically increasing the pulse width of the modulated signal while keeping a duty cycle of the modulated signal fixed.

Example 25. The method of one of examples 21 to 24, where monotonically increasing the pulse width of the modulated signal includes monotonically increasing the pulse width of the modulated signal by varying a duty cycle of the modulated signal.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

Circuits described herein may be reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples may be included in an integrated circuit and other elements may be external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated.

Modifications are possible in the described embodiments, and other embodiments are possible, within the scope of the claims.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. A device comprising:
modulation circuitry;
switch circuitry having a first terminal, a second terminal, and a third terminal, the first terminal of the switch circuitry coupled to the modulation circuitry;
pulse circuitry having a first terminal and a second terminal, the first terminal of the pulse circuitry coupled to the second terminal of the switch circuitry; and
an output stage coupled to the third terminal of the switch circuitry and the second terminal of the pulse circuitry.

2. The device of claim 1, wherein the switch circuitry is first switch circuitry, and the modulation circuitry includes:
loop filter circuitry having a terminal;
a signal generator having an inverting terminal and a non-inverting terminal;
second switch circuitry having a first terminal, a second terminal, and a third terminal, the first terminal of the second switch circuitry coupled to the inverting terminal of the signal generator, the second terminal of the second switch circuitry coupled to the non-inverting terminal of the signal generator; and
a comparator having a first terminal coupled to the terminal of the loop filter circuitry, a second terminal coupled to the third terminal of the second switch circuitry, and a third terminal coupled to the first terminal of the first switch circuitry.

3. The device of claim 2, wherein the terminal of the loop filter circuitry is a first terminal, the loop filter circuitry further having a second terminal, the comparator is a first comparator, and the modulation circuitry further includes a second comparator having a first terminal coupled to the second terminal of the loop filter circuitry, a second terminal coupled to the non-inverting terminal of the signal generator and the second terminal of the second switch circuitry, and a third terminal coupled to the output stage.

4. The device of claim 1, wherein the switch circuitry is first switch circuitry, and the pulse circuitry includes:
conversion logic having a first terminal and a second terminal, the first terminal of the conversion logic coupled to the second terminal of the first switch circuitry;
pulse generator circuitry having an a first terminal and a second terminal, the first terminal coupled to the second terminal of the conversion logic;
second switch circuitry having a first terminal, a second terminal, and a third terminal, the first terminal of the second switch circuitry coupled to the second terminal of the pulse generator circuitry; and
minimum pulse circuitry having a first terminal and a second terminal, the first terminal of the minimum pulse circuitry coupled to the second terminal of the second switch circuitry, the second terminal of the minimum pulse circuitry coupled to the output stage and the third terminal of the second switch circuitry.

5. The device of claim 4, wherein the pulse generator circuitry includes:
pulse adder circuitry having a first terminal, a second terminal, a third terminal, and a fourth terminal, the first terminal of the pulse adder circuitry coupled to the first terminal of the second switch circuitry;
a delay cell having a first terminal and a second terminal, the first terminal of the delay cell coupled to the second terminal of the pulse adder circuitry; and
a logic device having a first terminal coupled to the second terminal of the conversion logic and the third terminal of the pulse adder circuitry, a second terminal coupled to the second terminal of the delay cell, and a third terminal coupled to the fourth terminal of the pulse adder circuitry.

6. The device of claim 5, wherein the logic device is a first logic device, and the pulse adder circuitry includes:
a multiplexer having a first terminal, a second terminal, and a control terminal;
a first inverter having a first terminal and a second terminal, the first terminal of the first inverter coupled to the second terminal of the multiplexer;
a latch having a first terminal, a second terminal, and a third terminal, the first terminal of the latch coupled to the second terminal of the conversion logic and the first terminal of the multiplexer, the second terminal of the latch coupled to the second terminal of the first inverter;
a second logic device having a first terminal and a second terminal, the first terminal of the second logic device coupled to the first terminal of the second switch circuitry and the third terminal of the latch; and
a second inverter having a first terminal coupled to the control terminal of the multiplexer and a second terminal coupled to the first terminal of the delay cell and the second terminal of the second logic device.

7. The device of claim 4, wherein the minimum pulse circuitry includes:
first pulse adder circuitry having a first terminal, a second terminal, a third terminal and a fourth terminal, the first terminal of the first pulse adder circuitry coupled to the output stage;
a first delay cell having a first terminal and a second terminal, the first terminal of the first delay cell coupled to the second terminal of the first pulse adder circuitry;
a first logic device having a first terminal, a second terminal, and a third terminal, the first terminal of the first logic device coupled to the second terminal of the first delay cell;
an inverter having a first terminal and a second terminal, the first terminal of the inverter coupled to the second terminal of the second switch circuitry, the third terminal of the first pulse adder circuitry, and the second terminal of the first logic device;
second pulse adder circuitry having a first terminal, a second terminal, and a third terminal, the first terminal of the second pulse adder circuitry coupled to the second terminal of the inverter;
a second delay cell having a first terminal and a second terminal, the first terminal of the second delay cell coupled to the second terminal of the second pulse adder circuitry; and
a second logic device having a first terminal coupled to the third terminal of the first logic device, a second terminal coupled to the third terminal of the second pulse adder circuitry and the second terminal of the second delay cell, and a third terminal coupled to the fourth terminal of the first pulse adder circuitry.

8. The device of claim 1, wherein the switch circuitry further has a control terminal, the pulse circuitry further has a third terminal, and the device further comprising:
clock circuitry having a first terminal and a second terminal, the first terminal of the clock circuitry coupled to the modulation circuitry; and
a controller having a first terminal coupled to the second terminal of the clock circuitry, a second terminal coupled to the modulation circuitry and the control terminal of the switch circuitry, and a third terminal coupled to the third terminal of the pulse circuitry.

9. The device of claim 8, wherein the controller includes:
stepping select logic;
frequency stepping logic coupled to the stepping select logic and the clock circuitry;
soft stepping logic coupled to the stepping select logic and the control terminal of the switch circuitry; and
pulse width logic coupled to the soft stepping logic and the pulse circuitry.

10. A device comprising:
modulation circuitry capable of modulating audio signals to generate differential signals; and
pulse circuitry coupled to the modulation circuitry, the pulse circuitry capable of:
adjusting a pulse width of periodic pulses of the differential signals;
setting outputs using the differential signals;
increasing the pulse width of the periodic pulses across a plurality of cycles of the differential signals; and
after a determination that the pulse width is greater than or equal to a threshold pulse width, stop adjusting the pulse width of the differential signals.

11. The device of claim 10, wherein increasing the pulse width of periodic pulses comprises increasing the pulse width of the periodic pulses while maintaining a fixed duty cycle of the periodic pulses.

12. The device of claim 10, the modulation circuitry further capable of:
receiving a stepping control signal;
when the stepping control signal is asserted, generating the differential signals using a first class of modulation; and
when the stepping control signal is deasserted, generating the differential signals using a second class of modulation.

13. The device of claim 12, wherein the first class of modulation is AD modulation and the second class of modulation is BD modulation.

14. The device of claim 10, wherein the pulse circuitry is further capable of:
converting the differential signals from a first class of modulation to a second class of modulation; and
setting the pulse width of the periodic pulses of the converted signals.

15. The device of claim 10, wherein the pulse circuitry is further capable of:
extending a pulse of a first one of the differential signals by a minimum pulse width; and
adding a pulse having the minimum pulse width to a second one of the differential signals.

16. The device of claim 10, further comprising:
clock circuitry coupled to the modulation circuitry, the clock circuitry capable of setting a frequency of the differential signals using a clock signal; and
a controller coupled to the clock circuitry, the controller capable of controlling the frequency of the clock signal.

17. The device of claim 16, the controller capable of:
setting a frequency of the differential signals to a first frequency;
decreasing the frequency of the differential signals; and
after a determination that the frequency of the differential signals is less than or equal to a threshold frequency, stop adjusting the frequency of the differential signals, the threshold frequency corresponding to the threshold pulse width.

18. The device of claim 10, further comprising:
an output stage; and
switch circuitry coupled to the modulation circuitry, the pulse circuitry, and the output stage, the switch circuitry capable of providing the differential signals to one of the pulse circuitry or the output stage.

19. The device of claim 18, further comprising a controller coupled to the modulation circuitry, the pulse circuitry, and the switch circuitry, the controller capable of:
adjusting the modulation circuitry to use a first class of modulation;
after adjusting the modulation circuitry, adjusting the switch circuitry to provide the differential signals to the pulse circuitry; and
after the determination that the pulse width is greater than or equal to the threshold pulse width, adjusting the modulation circuitry to use a second class of modulation and adjusting the switch circuitry to provide the differential signals to the output stage.

20. The device of claim 10, wherein the pulse circuitry is further capable of:
after a determination to turn off the device, decreasing the pulse width of the periodic pulses across a plurality of cycles of the differential signals; and
after a determination that the pulse width is less than or equal to a minimum pulse width, stop adjusting the pulse width of the differential signals.

21. A method comprising:
receiving an audio signal;
modulating the audio signal to produce a modulated signal having a pulse width;
setting the pulse width of the modulated signal to a minimum pulse width;
providing the modulated signal having the minimum pulse width to a speaker;
after providing the modulated signal to the speaker, monotonically increasing the pulse width of the modulated signal; and
after the pulse width of the modulated signal is greater than or equal to a threshold, playing audio of the audio signal using the speaker.

22. The method of claim 21, further comprising:
determining a state of the audio signal; and
after determining the state of the audio signal is idle, decreasing the pulse width of the modulated signal by a set percentage.

23. The method of claim 21, wherein monotonically increasing the pulse width of the modulated signal comprises monotonically increasing the pulse width of the modulated signal by a set percentage.

24. The method of claim 21, wherein monotonically increasing the pulse width of the modulated signal comprises monotonically increasing the pulse width of the modulated signal while keeping a duty cycle of the modulated signal fixed.

25. The method of claim 21, wherein monotonically increasing the pulse width of the modulated signal comprises monotonically increasing the pulse width of the modulated signal by varying a duty cycle of the modulated signal.
